(19) United States
(12) Patent Application Publication
(10) Pub. No.: US 2024/0429281 A1
(43) Pub. Date: Dec. 26, 2024

(54) METAL GATES FOR SEMICONDUCTOR DEVICES AND METHOD THEREOF

(71) Applicant: Taiwan Semiconductor Manufacturing Company, Ltd., Hsin-Chu (TW)

(72) Inventors: Yu-Sheng Chen, New Taipei City (TW); Ju-Li Huang, Nantou County (TW); Shu-Hui Wang, Hsinchu City (TW); Jeng-Ya Yeh, New Taipei City (TW)

(21) Appl. No.: 18/339,596

(22) Filed: Jun. 22, 2023

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 27/092; H01L 29/42392; H01L 29/66439; H01L 29/66545; H01L 29/775; H01L 29/78696

(57) ABSTRACT

A method of manufacturing a semiconductor device includes forming a first stack of nanostructures suspended in a first region, a second stack of nanostructures suspended in a second region, and a third stack of nanostructures suspended in a third region, depositing a first work function (WF) layer wrapping around the nanostructures in the first, second, and third regions, removing the first WF layer from the first and second regions, depositing a second WF layer wrapping around the nanostructures in the first and second regions and over the first WF layer in the third region, removing the second WF layer from the first region, depositing a third WF layer wrapping around the nanostructures in the first region and over the second WF layer in the second and third regions, and forming a capping layer over the third WF layer in the first, second, and third regions.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller technology nodes, multi-gate metal-oxide-semiconductor field effect transistors (multi-gate MOSFETs, or multi-gate devices) have been introduced to improve gate control by increasing gate-channel coupling, reducing off-state current, and reducing short-channel effects (SCEs). A multi-gate device generally refers to a device having a gate structure (also known as gate stack), or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate structure on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. As device feature sizes continue to decrease, fine tuning work function (WF) layers in limited space available in ever-shrank gate structures, as an effort to implement different threshold voltages for multi-gate devices in one IC chip, is challenging. Therefore, while processes for multi-gate device formation have generally been adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates an example of multi-gate field-effect transistors (FETs) in a perspective view, in accordance with some embodiments of the present disclosure.

FIGS. 2, 3, 4, 5, 6, 7A, 7B, 8A, 8B, 9A, 9B, 9C, 9D, 10A, 10B, 11A, 11B, 12A, 12B, 13A, 13B, 14, 15, 16, 17, 18, 19, 20, 21, and 22 are views of intermediate stages in the manufacturing of the multi-gate FETs, in accordance with some embodiments of the present disclosure.

FIG. 23 is a flow chart of an example method for forming replacement gates for the multi-gate FETs, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about.” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices and the fabrication thereof, and more particularly to fabricating multi-gate transistors with multiple threshold voltages (Vt). The scheme of multiple threshold voltages is achieved by providing different configurations of material layers stacked in gate structures, in some embodiments of the present disclosure.

A multi-gate transistor generally refers to a device having a gate structure, or portion thereof, disposed over more than one side of a channel region. Multi-bridge-channel (MBC) transistors are examples of multi-gate devices that have become popular and promising candidates for high performance and low leakage applications. An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

The details of the structure and fabrication methods of the present disclosure are described below in conjunction with the accompanied drawings, which illustrate a process of making GAA transistors, according to some embodiments. A GAA transistor has vertically stacked horizontally-oriented channel layers. The channel layer may be referred to as “nanostructure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section. GAA transistors are promising candidates to take CMOS to the next stage of the roadmap due to their better gate control ability, lower leakage current, and fully FinFET device layout compatibility. For the purposes of simplicity, the present disclosure uses GAA devices as an example. Those of ordinary skill in the art should appreciate that they may readily use the present disclosure as a basis for designing or modifying other processes and structures (such as FinFET or other types of MBC transistors) for carrying out the same purposes and/or achieving the same advantages of the embodiments introduced herein.

To offer GAA transistors with different threshold voltages (such as standard Vt, high Vt, and so on), the formation of gate structures (e.g., a high-k metal gate, also referred to as HKMG) for GAA transistors includes depositing certain material layers, called work function (WF) layers, wrapping the vertically stacked channel layers. Through WF layers, transistors with different compositions of HKMG, thus different threshold voltages, can be formed. As the semiconductor fabrication process progresses to smaller geometries, the vertical space between channels of GAA transistors becomes smaller and the horizontal space between channels and nearby structures (such as dummy fins or another GAA transistor) becomes smaller, forming metal gates for GAA devices has become more and more challenging. For example, as transistor dimensions are continually scaled down to sub-3 nm technology nodes, it becomes difficult to deposit different WF layers to achieve different threshold voltages in the limited space vertically between the channel layers. This problem is exacerbated for certain IC applications where there is a need to implement transistors of the same type but with different threshold voltages. For example, in Static Random Access Memory (SRAM) devices, n-type field effect transistors (NFET) in a memory cell and an accompanied logic circuit may prefer different threshold voltages. An NFET in a memory cell may prefer a high threshold voltage for better low-leakage performance, while an NFET in a logic circuit configured to control the memory cell may prefer a low threshold voltage for a faster speed.

Embodiments of the present disclosure offer advantages over the existing art, though it is understood that other embodiments may offer different advantages, not all advantages are necessarily discussed herein, and no particular advantage is required for all embodiments. For example, the present disclosure may improve device performance, for example, by providing different threshold voltages for transistors in different regions of the device, particularly for IC applications such as SRAMs. The details of the fabrication methods and the structures of the present disclosure are described by referring to the accompanied figures.

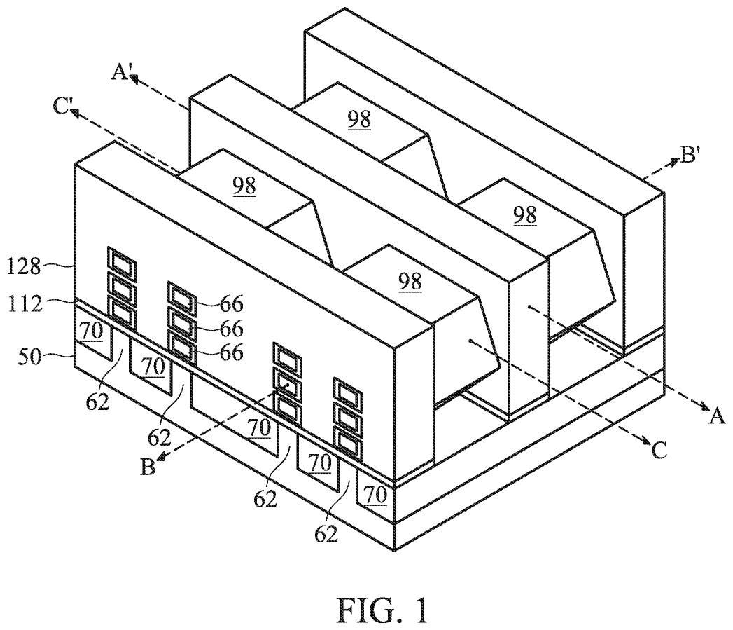

FIG. 1 illustrates an example of GAA transistors in accordance with some embodiments. FIG. 1 is a three-dimensional view, where some features of the GAA transistors are omitted for illustration clarity. The GAA transistors include nanostructures 66 (e.g., nanosheets, nanowires, or the like) over fins 62 on a substrate 50 (e.g., a semiconductor substrate), with the nanostructures 66 providing channel regions for the GAA transistors. The nanostructures 66 may also be referred to as channel layers. The nanostructures 66 may include p-type nanostructures, n-type nanostructures, or a combination thereof. Isolation regions 70, such as shallow trench isolation (STI) regions, are disposed between adjacent fins 62, which may protrude above and from between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may include a single material or a plurality of materials. In this context, the fins 62 refer to the portion extending above and from between the adjacent isolation regions 70.

A gate dielectric layer 112 is over top surfaces of the fins 62 and along top surfaces, sidewalls, and bottom surfaces of the nanostructures 66. A gate electrode 128 are over the gate dielectric layer 112. Epitaxial source/drain regions 98 are disposed on the fins 62 at opposing sides of the gate dielectric layer 112 and the gate electrode 128. The epitaxial source/drain regions 98 may be shared between various fins 62. For example, adjacent epitaxial source/drain regions 98 may be electrically connected, such as through coalescing the epitaxial source/drain regions 98 by epitaxial growth, or through coupling the epitaxial source/drain regions 98 with a same source/drain contact.

FIG. 1 further illustrates reference cross-sections that are used in later figures. Cross-section A-A′ is along a longitudinal axis of a gate electrode 128 and in a direction, for example, perpendicular to a direction of current flow between the epitaxial source/drain regions 98 of a GAA transistor. Cross-section B-B′ is along a longitudinal axis of a fin 62 and in a direction of, for example, a current flow between the epitaxial source/drain regions 98 of the GAA transistor. Cross-section C-C′ is parallel to cross-section A-A′ and extends through epitaxial source/drain regions 98 of the GAA transistor. Subsequent figures refer to these reference cross-sections for clarity.

Some embodiments discussed herein are discussed in the context of GAA transistors formed using a gate-last process. In other embodiments, a gate-first process may be used. Also, some embodiments contemplate aspects used in planar devices, such as planar FETs or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

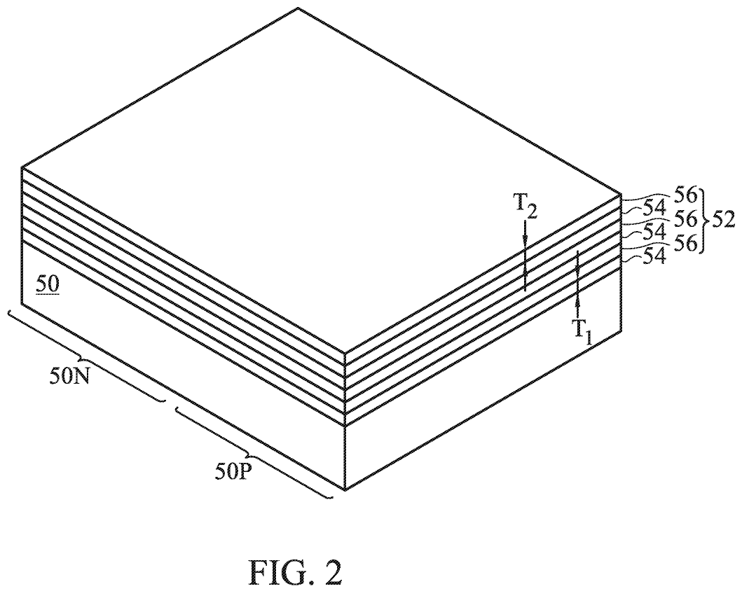

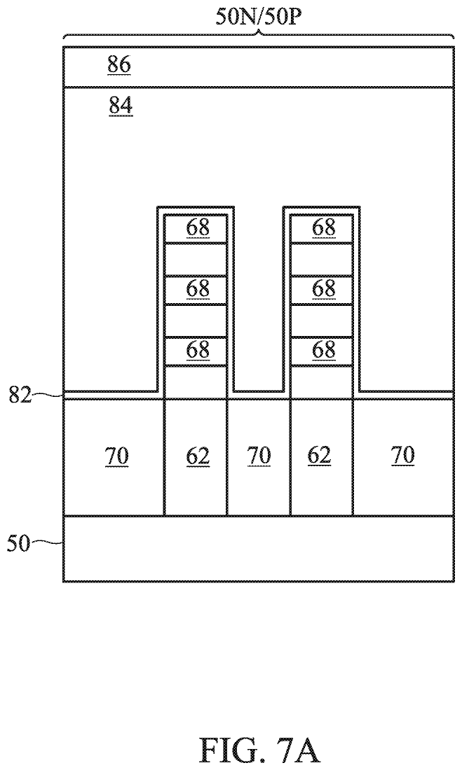

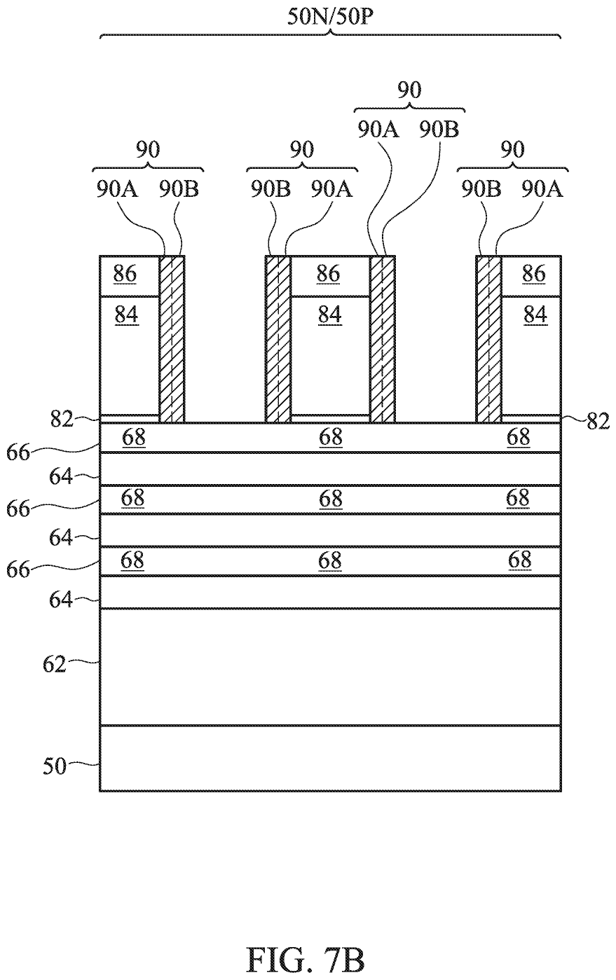

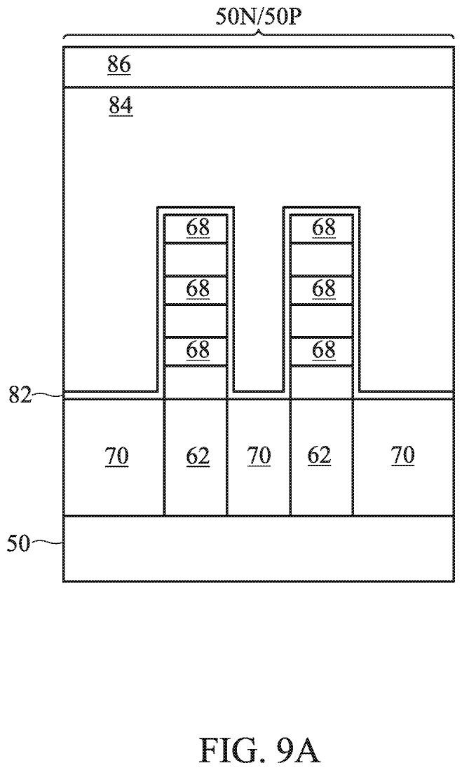

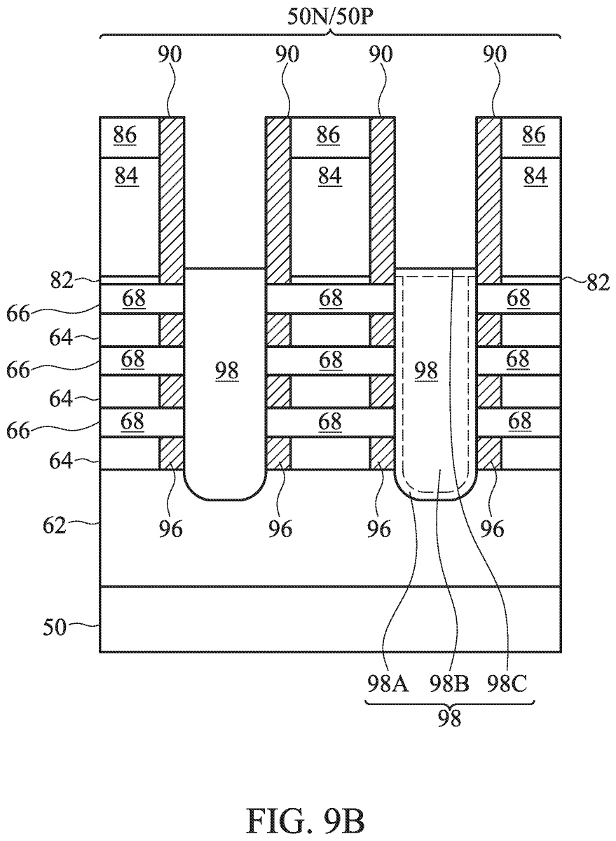

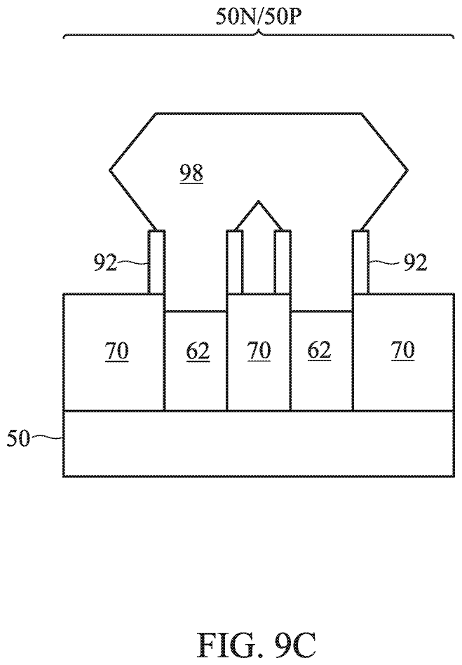

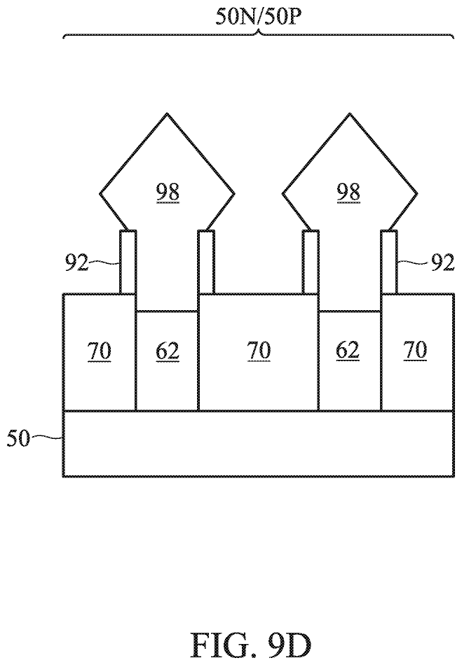

FIGS. 2 through 22 are views of intermediate stages in the manufacturing of GAA transistors, in accordance with some embodiments. FIGS. 2, 3, 4, 5, and 6 are perspective views showing a similar perspective view as FIG. 1. FIGS. 7A, 8A, 9A, 10A, 11A, 12A, 13A, 14, 15, 16, 17, 18, 19, 20, and 21 illustrate reference cross-section A-A′ illustrated in FIG. 1, except two fins are shown. FIGS. 7B, 8B, 9B, 10B, 11B, 12B, 13B, and 22 illustrate reference cross-section B-B′ illustrated in FIG. 1. FIGS. 9C and 9D illustrate reference cross-section C-C′ illustrated in FIG. 1, except two fins are shown.

In FIG. 2, a substrate 50 is provided for forming GAA transistors. The substrate 50 may be a semiconductor substrate, such as a bulk semiconductor, a semiconductor-on-insulator (SOI) substrate, or the like, which may be doped (e.g., with a p-type or a n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has a n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (not separately illustrated), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. As will be subsequently described in greater detail, the n-type regions 50N may include a first n-type region (denoted as 50N-1) with a first NFET threshold voltage and/or a second n-type region (denoted as 50N-2) with a second NFET threshold voltage, and similarly the p-type regions 50P may include a first p-type region (denoted as 50P-1) with a first PFET threshold voltage and/or a second p-type region (denoted as 50P-2) with a second PFET threshold voltage.

The substrate 50 may be lightly doped with a p-type or a n-type impurity. An anti-punch-through (APT) implantation may be performed on an upper portion of the substrate 50 to form an APT region. During the APT implantation, impurities may be implanted in the substrate 50. The impurities may have a conductivity type opposite from a conductivity type of source/drain regions that will be subsequently formed in each of the n-type region 50N and the p-type region 50P. The APT region may extend under the source/drain regions in the nano-FETs. The APT region may be used to reduce the leakage from the source/drain regions to the substrate 50. In some embodiments, the doping concentration in the APT region may be in the range of about 10¹⁸ cm⁻³ to about 10¹⁹ cm⁻³.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, the multi-layer stack 52 includes three layers of each of the first semiconductor layers 54 and the second semiconductor layers 56. It should be appreciated that the multi-layer stack 52 may include any number of the first semiconductor layers 54 and the second semiconductor layers 56.

In the illustrated embodiment, and as will be subsequently described in greater detail, the first semiconductor layers 54 will be removed and the second semiconductor layers 56 will be patterned to form channel regions for the GAA transistors in both the n-type region 50N and the p-type region 50P. The first semiconductor layers 54 are sacrificial layers (or dummy layers), which will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nano-FETs in one region (e.g., the p-type region 50P), and the second semiconductor layers 56 will be patterned to form channel regions for nano-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without removing the second semiconductor layers 56 in the n-type region 50N, and the second semiconductor layers 56 may be removed without removing the first semiconductor layers 54 in the p-type region 50P.

Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. Each of the layers may have a small thickness, such as a thickness in a range of about 5 nm to about 30 nm. In some embodiments, some layers (e.g., the second semiconductor layers 56) are formed to be thinner than other layers (e.g., the first semiconductor layers 54). For example, in embodiments in which the first semiconductor layers 54 are sacrificial layers (or dummy layers) and the second semiconductor layers 56 are patterned to form channel regions for the GAA transistors in both the n-type region 50N and the p-type region 50P, the first semiconductor layers 54 can have a first thickness T₁ and the second semiconductor layers 56 can have a second thickness T₂, with the second thickness T₂ being from about 30% to about 60% less than the first thickness T₁. Forming the second semiconductor layers 56 to a smaller thickness allows the channel regions to be formed at a greater density.

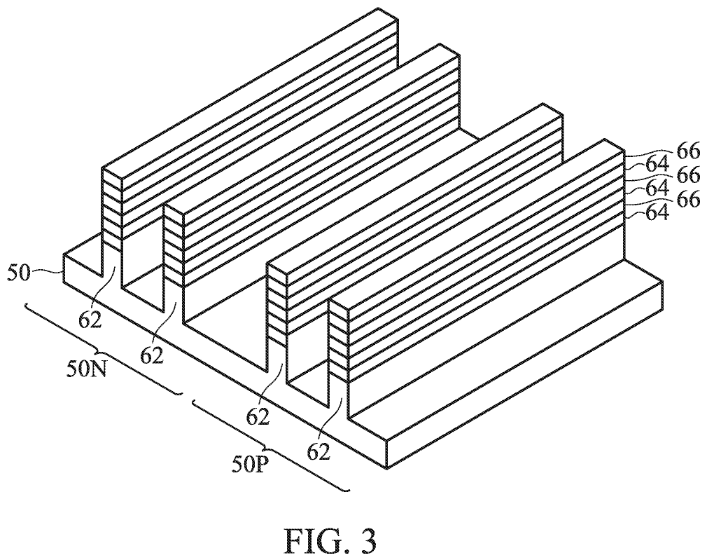

In FIG. 3, trenches are patterned in the substrate 50 and the multi-layer stack 52 to form fins 62, first nanostructures 64, and second nanostructures 66. The fins 62 are semiconductor strips patterned in the substrate 50. The first nanostructures 64 and the second nanostructures 66 include the remaining portions of the first semiconductor layers 54 and the second semiconductor layers 56, respectively. The trenches may be patterned by any acceptable etch process, such as a reactive ion etch (RIE), neutral beam etch (NBE), the like, or a combination thereof. The etching may be anisotropic.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 62 and the nanostructures 64, 66. In some embodiments, the mask (or other layer) may remain on the nanostructures 64, 66.

The fins 62 and the nanostructures 64, 66 may each have widths in a range of about 8 nm to about 40 nm. In the illustrated embodiment, the fins 62 and the nanostructures 64, 66 have substantially equal widths in the n-type region 50N and the p-type region 50P. In another embodiment, the fins 62 and the nanostructures 64, 66 in one region (e.g., the n-type region 50N) are wider or narrower than the fins 62 and the nanostructures 64, 66 in another region (e.g., the p-type region 50P).

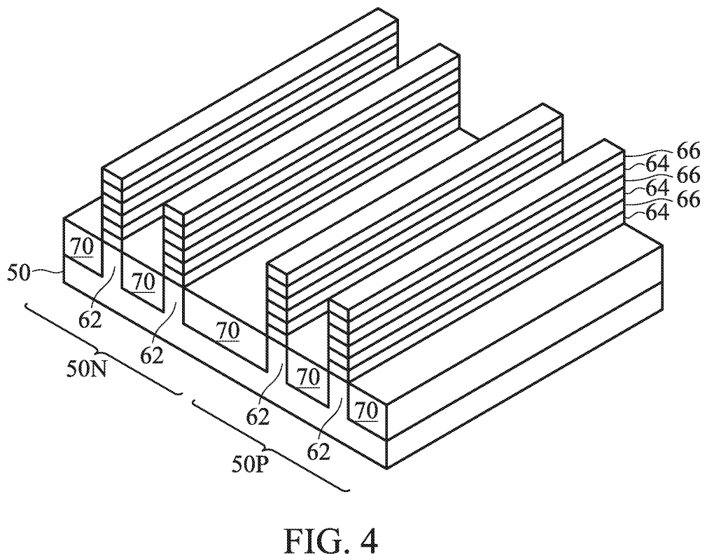

In FIG. 4, STI regions 70 are formed over the substrate 50 and between adjacent fins 62. The STI regions 70 are disposed around at least a portion of the fins 62 such that at least a portion of the nanostructures 64, 66 protrude from between adjacent STI regions 70. In the illustrated embodiment, the top surfaces of the STI regions 70 are coplanar (within process variations) with the top surfaces of the fins 62. In some embodiments, the top surfaces of the STI regions 70 are above or below the top surfaces of the fins 62. The STI regions 70 separate the features of adjacent devices.

The STI regions 70 may be formed by any suitable method. For example, an insulation material can be formed over the substrate 50 and the nanostructures 64, 66, and between adjacent fins 62. The insulation material may be an oxide, such as silicon oxide, a nitride, such as silicon nitride, the like, or a combination thereof, which may be formed by a chemical vapor deposition (CVD) process, such as high-density plasma CVD (HDP-CVD), flowable CVD (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the nanostructures 64, 66. Although the STI regions 70 are each illustrated as a single layer, some embodiments may utilize multiple layers. For example, in some embodiments a liner (not separately illustrated) may first be formed along surfaces of the substrate 50, the fins 62, and the nanostructures 64, 66. Thereafter, a fill material, such as those previously described may be formed over the liner.

A removal process is then applied to the insulation material to remove excess insulation material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulation material are coplanar (within process variations) after the planarization process is complete. In embodiments in which a mask remains on the nanostructures 64, 66, the planarization process may expose the mask or remove the mask such that top surfaces of the mask or the nanostructures 64, 66, respectively, and the insulation material are coplanar (within process variations) after the planarization process is complete. The insulation material is then recessed to form the STI regions 70. The insulation material is recessed such that at least a portion of the nanostructures 64, 66 protrude from between adjacent portions of the insulation material. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The insulation material may be recessed using any acceptable etching process, such as one that is selective to the material of the insulation material (e.g., selectively etches the insulation material of the STI regions 70 at a faster rate than the materials of the fins 62 and the nanostructures 64, 66). For example, an oxide removal may be performed using dilute hydrofluoric (dHF) acid.

The process previously described is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the substrate 50, the fins 62, and/or the nanostructures 64, 66. The wells may have a conductivity type opposite from a conductivity type of source/drain regions that will be subsequently formed in each of the n-type region 50N and the p-type region 50P. In some embodiments, a p-type well is formed in the n-type region 50N, and a n-type well is formed in the p-type region 50P. In some embodiments, a p-type well or a n-type well is formed in both the n-type region 50N and the p-type region 50P.

In embodiments with different well types, different implant steps for the n-type region 50N and the p-type region 50P may be achieved using mask (not separately illustrated) such as a photoresist. For example, a photoresist may be formed over the fins 62, the nanostructures 64, 66, and the STI regions 70 in the n-type region 50N. The photoresist is patterned to expose the p-type region 50P. The photoresist can be formed by using a spin-on technique and can be patterned using acceptable photolithography techniques. Once the photoresist is patterned, a n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of about 10¹³ cm⁻³ to about 10¹⁴ cm⁻³. After the implant, the photoresist may be removed, such as by any acceptable ashing process.

Following or prior to the implanting of the p-type region 50P, a mask (not separately illustrated) such as a photoresist is formed over the fins 62, the nanostructures 64, 66, and the STI regions 70 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of about 10¹³ cm⁻³ to about 10¹⁴ cm⁻³. After the implant, the photoresist may be removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the fins 62 and/or the nanostructures 64, 66, the grown materials may be in-situ doped during growth, which may obviate the implantations, although in-situ and implantation doping may be used together.

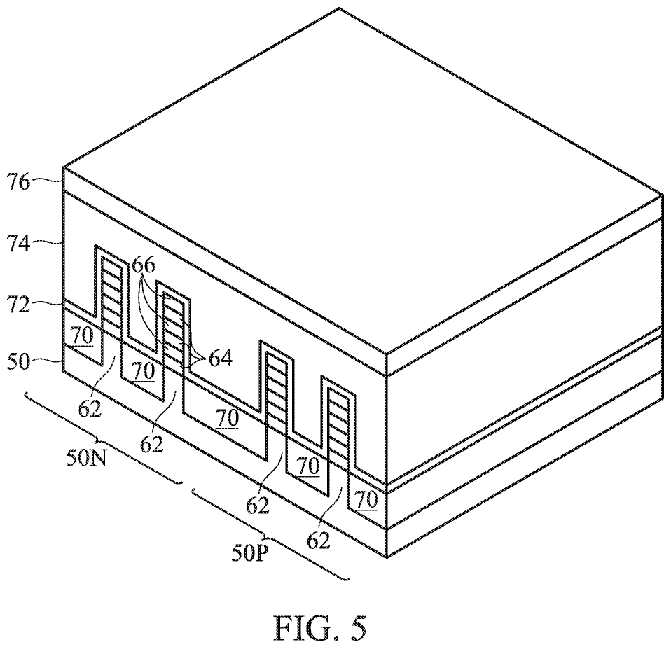

In FIG. 5, a dummy dielectric layer 72 is formed on the fins 62 and the nanostructures 64, 66. The dummy dielectric layer 72 may be formed of a dielectric material such as silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer 74 may be formed of material(s) that have a high etching selectivity from the etching of insulation materials, e.g., the STI regions 70 and/or the dummy dielectric layer 72. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the fins 62, the nanostructures 64, 66, and the STI regions 70, such that the dummy dielectric layer 72 extends over the STI regions 70 and between the dummy gate layer 74 and the STI regions 70. In another embodiment, the dummy dielectric layer 72 covers only the fins 62 and the nanostructures 64, 66.

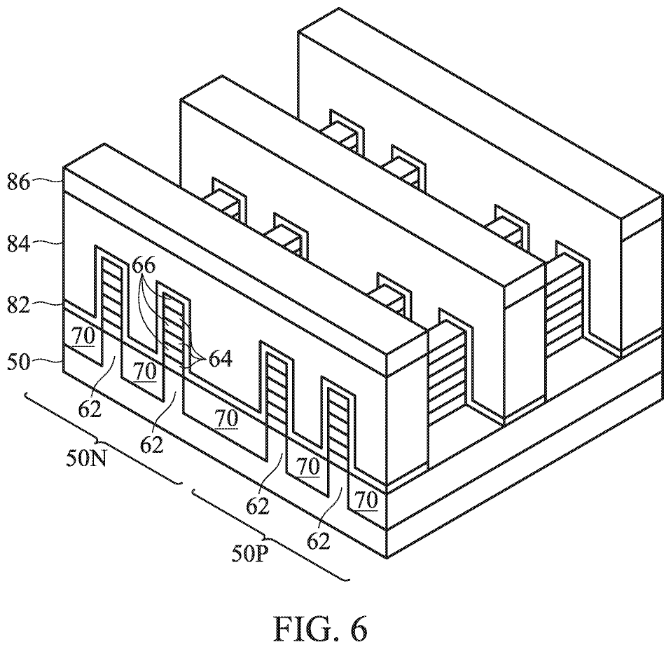

In FIG. 6, the mask layer 76 is patterned using acceptable photolithography and etching techniques to form masks 86. The pattern of the masks 86 is then transferred to the dummy gate layer 74 by any acceptable etching technique to form dummy gates 84. The pattern of the masks 86 may optionally be further transferred to the dummy dielectric layer 72 by any acceptable etching technique to form dummy dielectrics 82. The dummy gates 84 cover portions of the nanostructures 64, 66 that will be exposed in subsequent processing to form channel regions. Specifically, the dummy gates 84 extend along the portions of the nanostructures 66 that will be patterned to form channel regions 68. The pattern of the masks 86 may be used to physically separate adjacent dummy gates 84. The dummy gates 84 may also have lengthwise directions substantially perpendicular (within process variations) to the lengthwise directions of the fins 62. The masks 86 can optionally be removed after patterning, such as by any acceptable etching technique.

FIGS. 7A through 22 illustrate various additional steps in the manufacturing of embodiment devices. In FIGS. 7A and 7B, gate spacers 90 are formed over the nanostructures 64, 66, on exposed sidewalls of the masks 86 (if present), the dummy gates 84, and the dummy dielectrics 82. The gate spacers 90 may be formed by conformally depositing one or more dielectric material(s) and subsequently etching the dielectric material(s). Acceptable dielectric materials include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like; multilayers thereof; or the like. The dielectric materials may be formed by a conformal deposition process such as chemical vapor deposition (CVD), plasma enhanced chemical vapor deposition (PECVD), atomic layer deposition (ALD), or the like. In the illustrated embodiment, the gate spacers 90 each include multiple layers, e.g., a first spacer layer 90A and a second spacer layer 90B. In some embodiments, the first spacer layers 90A and the second spacer layers 90B are formed of silicon oxycarbonitride (e.g., SiOₓN_{y}C_{1-x-y}, where x and y are in the range of 0 to 1). For example, the first spacer layers 90A can be formed of a similar or a different composition of silicon oxycarbonitride than the second spacer layers 90B. An acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). After etching, the gate spacers 90 can have straight sidewalls (as illustrated) or can have curved sidewalls (not illustrated). As will be subsequently described in greater detail, the dielectric material(s), when etched, may have portions left on the sidewalls of the fins 62 and/or the nanostructures 64, 66 (thus forming fin spacers).

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the fins 62 and/or the nanostructures 64, 66 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the fins 62 and/or the nanostructures 64, 66 exposed in the n-type region 50N. The mask may then be removed. The n-type impurities may be any of the n-type impurities previously described, and the p-type impurities may be any of the p-type impurities previously described. During the implanting, the channel regions 68 remain covered by the dummy gates 84, so that the channel regions 68 remain substantially free of the impurity implanted to form the LDD regions. The LDD regions may have a concentration of impurities in the range of about 10¹⁵ cm⁻³ to about 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

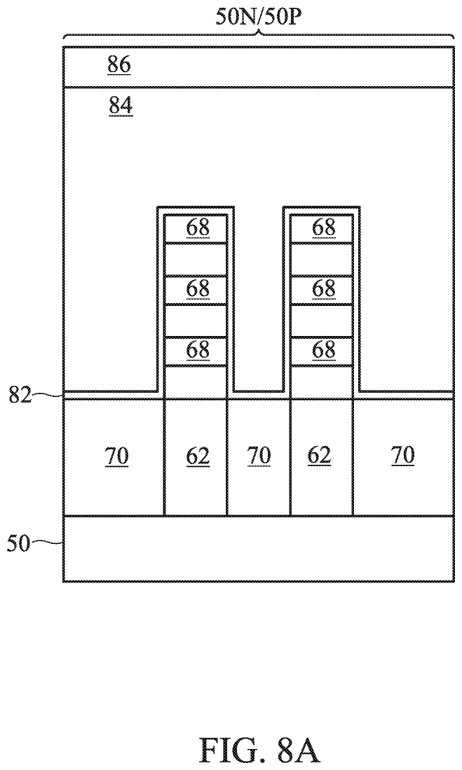

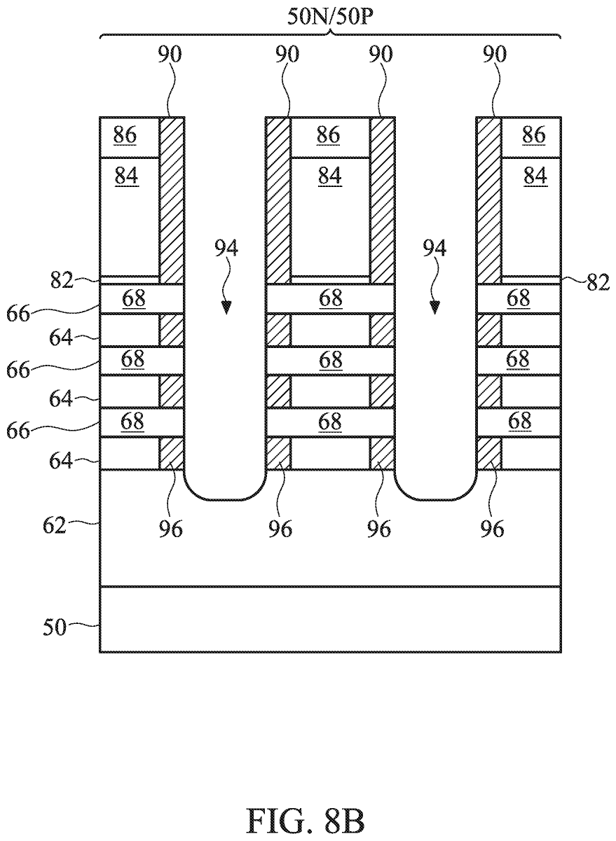

In FIGS. 8A and 8B, source/drain recesses 94 are formed in the nanostructures 64, 66. In the illustrated embodiment, the source/drain recesses 94 extend through the nanostructures 64, 66 and into the fins 62. The source/drain recesses 94 may also extend into the substrate 50. In various embodiments, the source/drain recesses 94 may extend to a top surface of the substrate 50 without etching the substrate 50; the fins 62 may be etched such that bottom surfaces of the source/drain recesses 94 are disposed below the top surfaces of the STI regions 70; or the like. The source/drain recesses 94 may be formed by etching the nanostructures 64, 66 using an anisotropic etching processes, such as a RIE, a NBE, or the like. The gate spacers 90 and the dummy gates 84 collectively mask portions of the fins 62 and/or the nanostructures 64, 66 during the etching processes used to form the source/drain recesses 94. A single etch process may be used to etch each of the nanostructures 64, 66, or multiple etch processes may be used to etch the nanostructures 64, 66. Timed etch processes may be used to stop the etching of the source/drain recesses 94 after the source/drain recesses 94 reach a desired depth.

Optionally, inner spacers 96 are formed on the sidewalls of the remaining portions of the first nanostructures 64, e.g., those sidewalls exposed by the source/drain recesses 94. As will be subsequently described in greater detail, source/drain regions will be subsequently formed in the source/drain recesses 94, and the first nanostructures 64 will be subsequently replaced with corresponding gate structures. The inner spacers 96 act as isolation features between the subsequently formed source/drain regions and the subsequently formed gate structures. Further, the inner spacers 96 may be used to substantially prevent damage to the subsequently formed source/drain regions by subsequent etching processes, such as etching processes used to subsequently remove the first nanostructures 64.

As an example to form the inner spacers 96, the source/drain recesses 94 can be laterally expanded. Specifically, portions of the sidewalls of the first nanostructures 64 exposed by the source/drain recesses 94 may be recessed. Although sidewalls of the first nanostructures 64 are illustrated as being straight, the sidewalls may be concave or convex. The sidewalls may be recessed by any acceptable etching process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the first nanostructures 64. The inner spacers 96 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 96 are illustrated as being flush with respect to the sidewalls of the gate spacers 90, the outer sidewalls of the inner spacers 96 may extend beyond or be recessed from the sidewalls of the gate spacers 90. In other words, the inner spacers 96 may partially fill, completely fill, or overfill the sidewall recesses. Moreover, although the sidewalls of the inner spacers 96 are illustrated as being straight, the sidewalls of the inner spacers 96 may be concave or convex.

In FIGS. 9A and 9B, epitaxial source/drain regions 98 are formed in the source/drain recesses 94. The epitaxial source/drain regions 98 are formed in the source/drain recesses 94 such that each dummy gate 84 (and corresponding channel regions 68) is disposed between respective adjacent pairs of the epitaxial source/drain regions 98. In some embodiments, the gate spacers 90 and the inner spacers 96 are used to separate the epitaxial source/drain regions 98 from, respectively, the dummy gates 84 and the first nanostructures 64 by an appropriate lateral distance so that the epitaxial source/drain regions 98 do not short out with subsequently formed gates of the resulting GAA transistors. A material of the epitaxial source/drain regions 98 may be selected to exert stress in the respective channel regions 68, thereby improving performance.

The epitaxial source/drain regions 98 in the n-type region 50N may be formed by masking the p-type region 50P. Then, the epitaxial source/drain regions 98 in the n-type region 50N are epitaxially grown in the source/drain recesses 94 in the n-type region 50N. The epitaxial source/drain regions 98 may include any acceptable material appropriate for n-type devices. For example, the epitaxial source/drain regions 98 in the n-type region 50N may include materials exerting a tensile strain on the channel regions 68, such as silicon, silicon carbide, phosphorous doped silicon carbide, silicon phosphide, or the like. The epitaxial source/drain regions 98 in the n-type region 50N may have surfaces raised from respective surfaces of the fins 62 and the nanostructures 64, 66, and may have facets.

The epitaxial source/drain regions 98 in the p-type region 50P may be formed by masking the n-type region 50N. Then, the epitaxial source/drain regions 98 in the p-type region 50P are epitaxially grown in the source/drain recesses 94 in the p-type region 50P. The epitaxial source/drain regions 98 may include any acceptable material appropriate for p-type devices. For example, the epitaxial source/drain regions 98 in the p-type region 50P may include materials exerting a compressive strain on the channel regions 68, such as silicon germanium, boron doped silicon germanium, germanium, germanium tin, or the like. The epitaxial source/drain regions 98 in the p-type region 50P may have surfaces raised from respective surfaces of the fins 62 and the nanostructures 64, 66, and may have facets.

The epitaxial source/drain regions 98, the nanostructures 64, 66, and/or the fins 62 may be implanted with impurities to form source/drain regions, similar to the process previously described for forming LDD regions, followed by an anneal. The source/drain regions may have an impurity concentration in the range of about 10¹⁹ cm⁻³ to about 10²¹ cm⁻³. The n-type and/or p-type impurities for source/drain regions may be any of the impurities previously described. In some embodiments, the epitaxial source/drain regions 98 may be in situ doped during growth.

As a result of the epitaxy processes used to form the epitaxial source/drain regions 98, upper surfaces of the epitaxial source/drain regions have facets which expand laterally outward beyond sidewalls of the fins 62 and the nanostructures 64, 66. In some embodiments, these facets cause adjacent epitaxial source/drain regions 98 to merge as illustrated by FIG. 9C. In some embodiments, adjacent epitaxial source/drain regions 98 remain separated after the epitaxy process is completed as illustrated by FIG. 9D. In the illustrated embodiments, the spacer etch used to form the gate spacers 90 is adjusted to also form fin spacers 92 on sidewalls of the fins 62 and/or the nanostructures 64, 66. The fin spacers 92 are formed to cover a portion of the sidewalls of the fins 62 and/or the nanostructures 64, 66 that extend above the STI regions 70, thereby blocking the epitaxial growth. In another embodiment, the spacer etch used to form the gate spacers 90 is adjusted to not form fin spacers, so as to allow the epitaxial source/drain regions 98 to extend to the surface of the STI regions 70.

The epitaxial source/drain regions 98 may include one or more semiconductor material layers. For example, the epitaxial source/drain regions 98 may each include a liner layer 98A, a main layer 98B, and a finishing layer 98C (or more generally, a first semiconductor material layer, a second semiconductor material layer, and a third semiconductor material layer). Any number of semiconductor material layers may be used for the epitaxial source/drain regions 98. Each of the liner layer 98A, the main layer 98B, and the finishing layer 98C may be formed of different semiconductor materials and may be doped to different impurity concentrations. In some embodiments, the liner layer 98A may have a lesser concentration of impurities than the main layer 98B, and the finishing layer 98C may have a greater concentration of impurities than the liner layer 98A and a lesser concentration of impurities than the main layer 98B. In embodiments in which the epitaxial source/drain regions 98 include three semiconductor material layers, the liner layers 98A may be grown in the source/drain recesses 94, the main layers 98B may be grown on the liner layers 98A, and the finishing layers 98C may be grown on the main layers 98B.

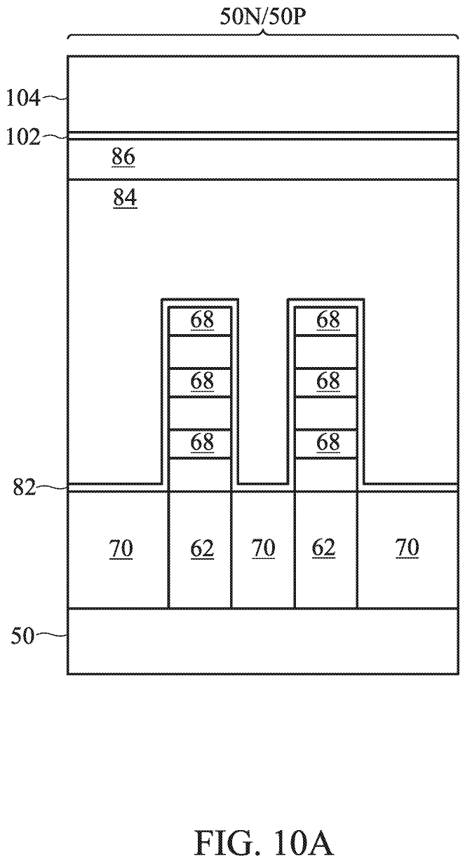

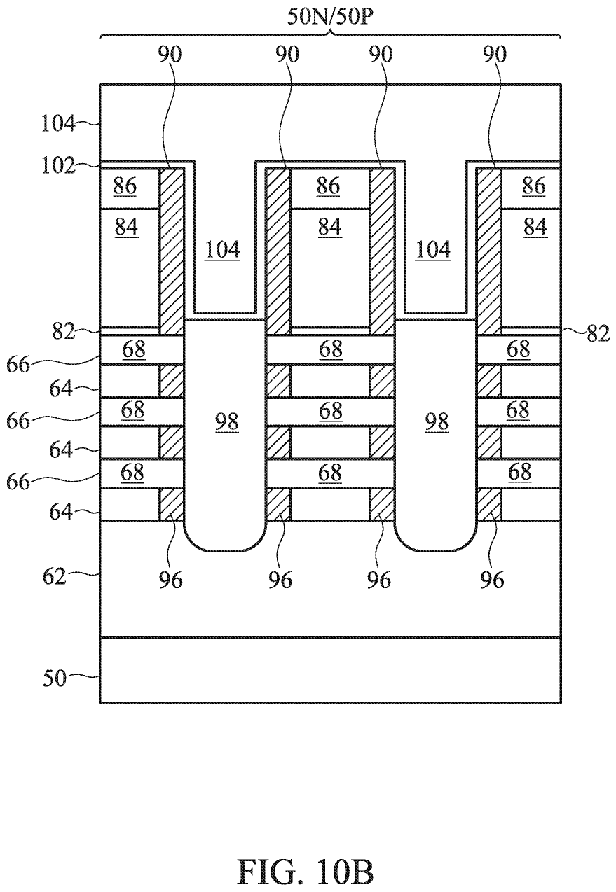

In FIGS. 10A and 10B, a first inter-layer dielectric (ILD) 104 is deposited over the epitaxial source/drain regions 98, the gate spacers 90, the masks 86 (if present) or the dummy gates 84. The first ILD 104 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 102 is formed between the first ILD 104 and the epitaxial source/drain regions 98, the gate spacers 90, and the masks 86 (if present) or the dummy gates 84. The CESL 102 may be formed of a dielectric material, such as silicon nitride, silicon oxide, silicon oxynitride, or the like, having a high etching selectivity from the etching of the first ILD 104. The CESL 102 may be formed by an any suitable method, such as CVD, ALD, or the like.

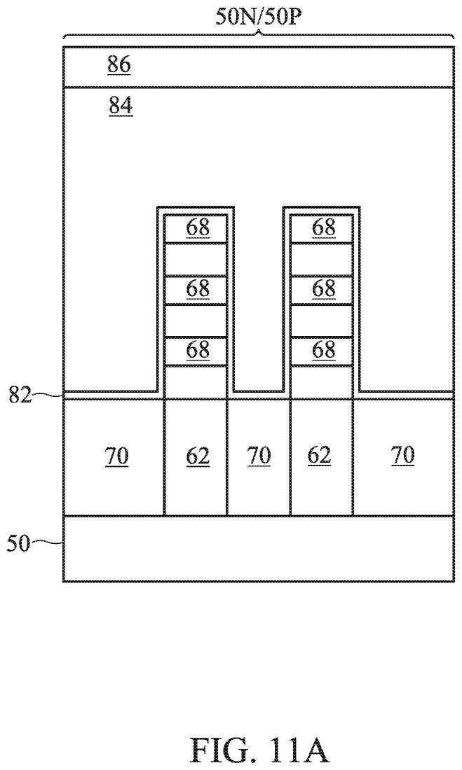

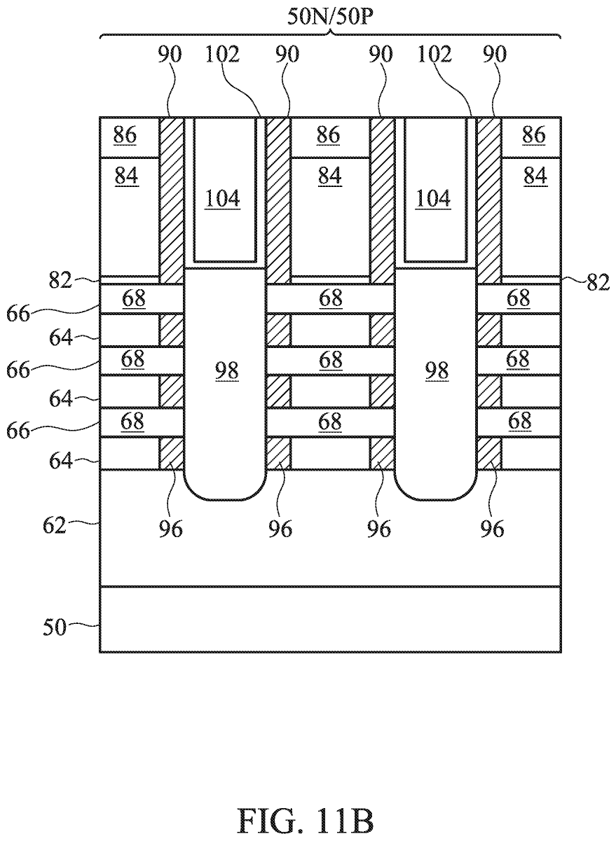

In FIGS. 11A and 11B, a removal process is performed to level the top surfaces of the first ILD 104 with the top surfaces of the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, the top surfaces of the gate spacers 90, the first ILD 104, the CESL 102, and the masks 86 (if present) or the dummy gates 84 are coplanar (within process variations). Accordingly, the top surfaces of the masks 86 (if present) or the dummy gates 84 are exposed through the first ILD 104. In the illustrated embodiment, the masks 86 remain, and the planarization process levels the top surfaces of the first ILD 104 with the top surfaces of the masks 86.

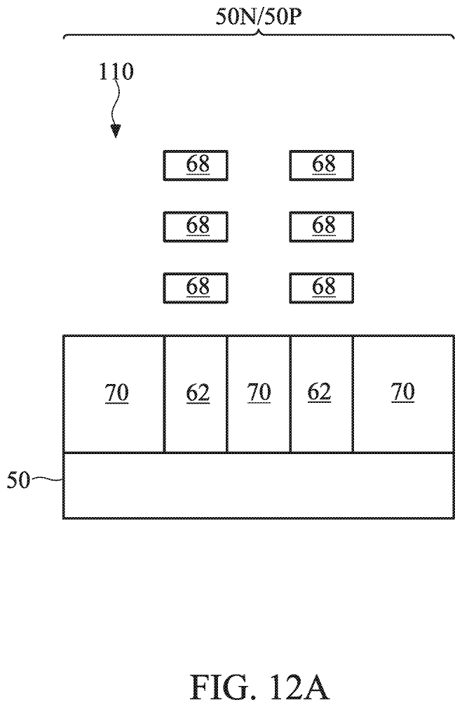

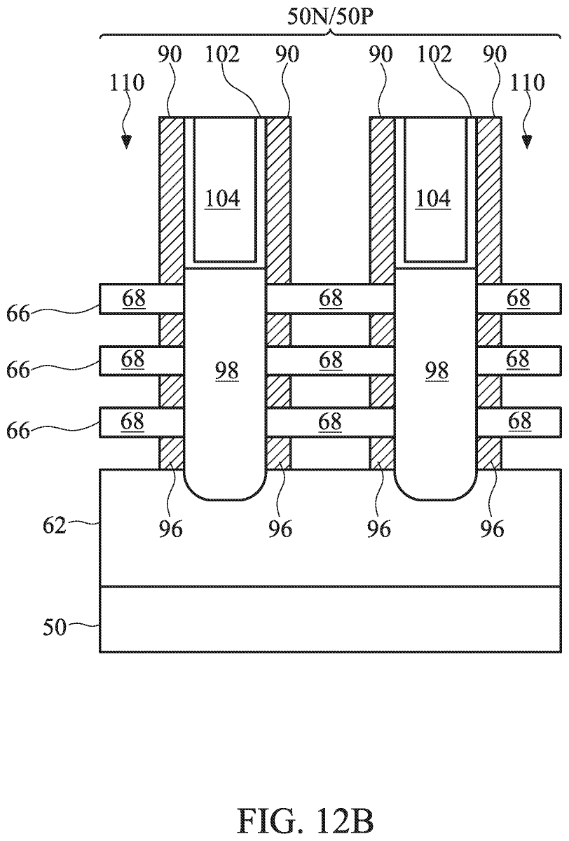

In FIGS. 12A and 12B, the masks 86 (if present) and the dummy gates 84 are removed in an etching process, so that recesses 110 are formed. Portions of the dummy dielectrics 82 in the recesses 110 are also removed. In some embodiments, the dummy gates 84 are removed by an anisotropic dry etch process. For example, the etching process may include a dry etch process using reaction gas(es) that selectively etch the dummy gates 84 at a faster rate than the first ILD 104 or the gate spacers 90. During the removal, the dummy dielectrics 82 may be used as etch stop layers when the dummy gates 84 are etched. The dummy dielectrics 82 are then removed. Each recess 110 exposes and/or overlies portions of the channel regions 68. Portions of the second nanostructures 66 which act as the channel regions 68 are disposed between adjacent pairs of the epitaxial source/drain regions 98.

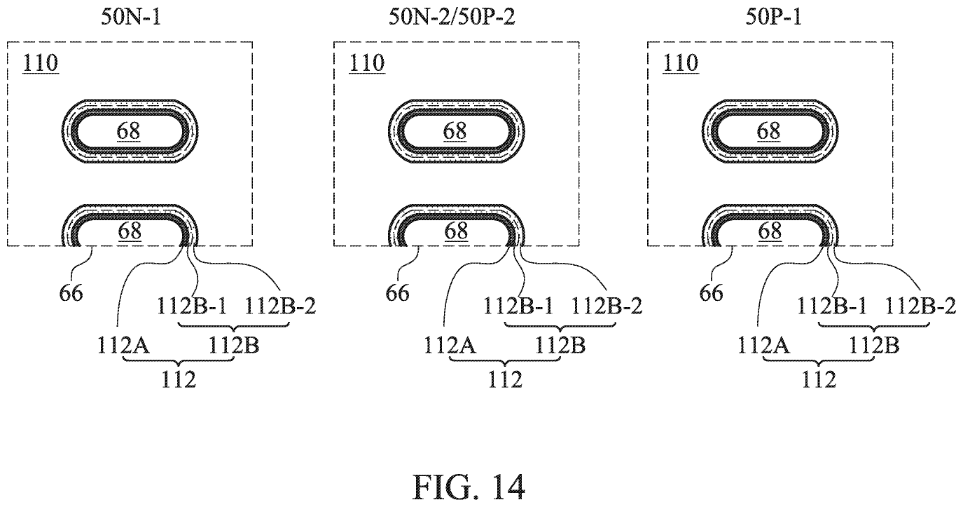

The remaining portions of the first nanostructures 64 are then removed to expand the recesses 110. The remaining portions of the first nanostructures 64 can be removed by any acceptable etching process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66. As illustrated more clearly in FIGS. 14 through 22 (subsequently described in greater detail), the remaining portions of the second nanostructures 66 can have rounded corners.

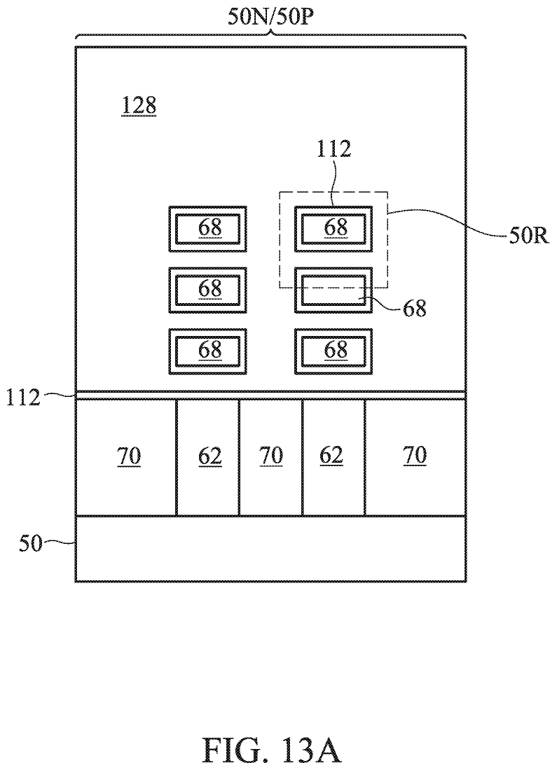

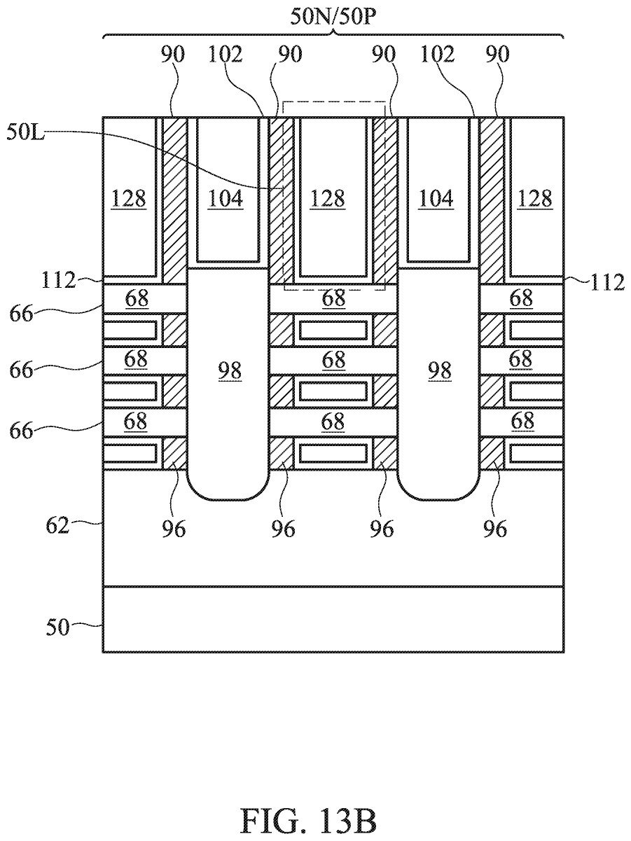

In FIGS. 13A and 13B, a gate dielectric layer 112 is formed in the recesses 110. A gate electrode layer 128 is formed on the gate dielectric layer 112. The gate dielectric layer 112 and the gate electrode layer 128 are layers for replacement gates, and each wrap around all (e.g., four) sides of the second nanostructures 66.

The gate dielectric layer 112 is disposed on the sidewalls and/or the top surfaces of the fins 62; on the top surfaces, the sidewalls, and the bottom surfaces of the second nanostructures 66; and on the sidewalls of the gate spacers 90. The gate dielectric layer 112 may also be formed on the top surfaces of the first ILD 104 and the gate spacers 90. The gate dielectric layer 112 may include an oxide such as silicon oxide or a metal oxide, a silicate such as a metal silicate, combinations thereof, multi-layers thereof, or the like. The gate dielectric layer 112 may include a dielectric material having a k-value greater than about 7.0, such as a metal oxide or a silicate of hafnium, aluminum, zirconium, lanthanum, manganese, barium, titanium, lead, and combinations thereof. Although a single layered gate dielectric layer 112 is illustrated in FIGS. 13A and 13B, as will be subsequently described in greater detail, the gate dielectric layer 112 may include an interfacial layer and a main layer.

The gate electrode layer 128 may include a metal-containing material such as titanium nitride, titanium oxide, tantalum nitride, tantalum carbide, cobalt, ruthenium, aluminum, tungsten, combinations thereof, multi-layers thereof, or the like. Although a single-layered gate electrode layer 128 is illustrated in FIGS. 13A and 13B, as will be subsequently described in greater detail, the gate electrode layer 128 may include any number of work function tuning layers, any number of barrier layers, any number of glue layers, and a fill material.

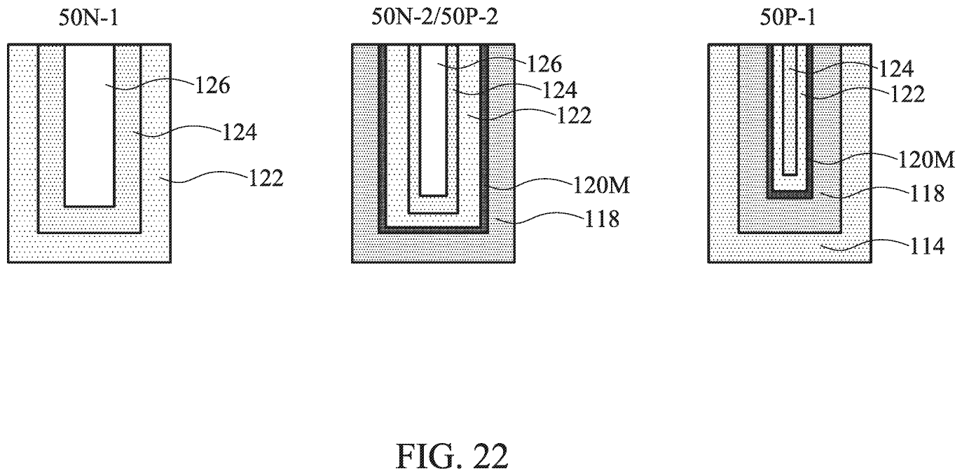

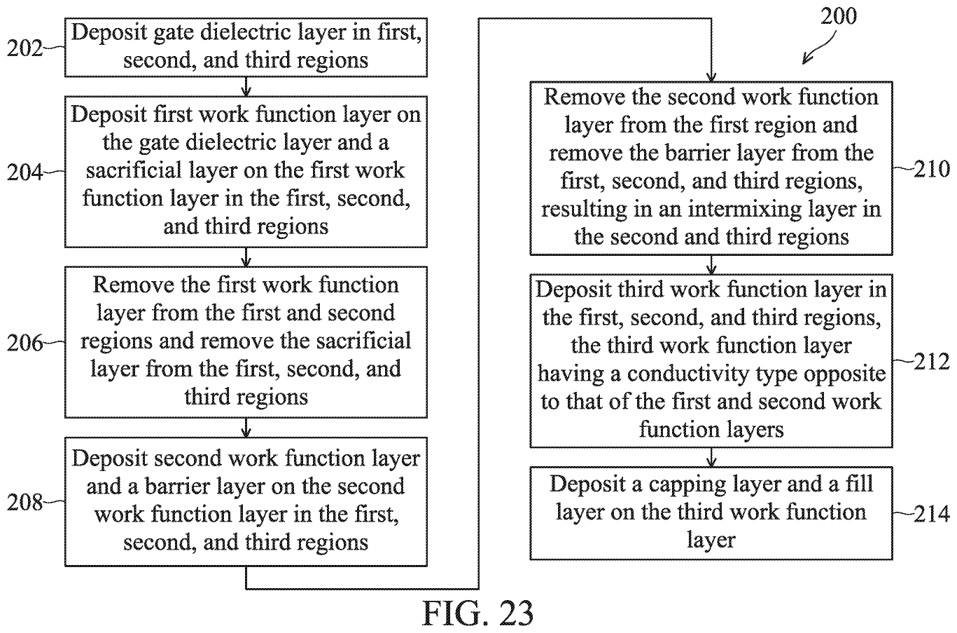

FIGS. 14 through 22 illustrate a process in which material layers for replacement gates are formed in the recesses 110. In FIGS. 14 through 21, features in regions that are similar to a region 50R in FIG. 13A are illustrated. In FIG. 22, features in regions that are similar to a region 50L in FIG. 13B are illustrated. FIG. 23 is a flow chart of an example method 200 for forming the replacement gate layers, in accordance with some embodiments. FIGS. 14 through 22 are described in conjunction with FIG. 23.

In accordance with some embodiments of the present disclosure, when forming the replacement gates, a first configuration of material layers, a second configuration of material layers, and a third configuration of material layers are formed in the recesses 110 in different regions of the n-type region(s) 50N and p-type region(s) 50P. Particularly, the first configuration of material layers is formed in a first n-type region 50N (denoted as “50N-1” in figures) providing a first NFET threshold voltage, and the third configuration of material layer is formed in a first p-type region 50P (denoted as “50P-1” in figures) providing a first PFET threshold voltage. The second configuration of material layers may be formed in a second n-type region and/or a second p-type region (collectively denoted as “50N-2/50P-2” in figures). In some embodiments, the second configuration of material layers may be formed in a second n-type region providing a second NFET threshold voltage that is higher than the first NFET threshold voltage. That is, the scheme may provide transistors in the n-type regions 50N with two NFET threshold voltages. In some alternative embodiments, the second configuration of material layers may be formed in a second p-type region providing a second PFET threshold voltage that is higher than the first PFET threshold voltage. That is, the scheme may provide transistors in the p-type regions 50P with two PFET threshold voltages. In some other alternative embodiments, the second configuration may be formed simultaneously in a second n-type region providing a second NFET threshold voltage that is higher than the first NFET threshold voltage and in a second p-type region providing a second PFET threshold voltage that is higher than the first PFET threshold voltage. That is, the scheme may provide transistors in the n-type regions 50N with two NFET threshold voltages and transistors in the p-type regions 50P with two PFET threshold voltages. In one particular example of an SRAM device, the first configuration of material layers is for NFETs in logic circuits with a relatively lower threshold voltage, the second configuration of material layers is for NFETs in memory cells with a relatively higher threshold voltage, and the third configuration of material layers is for PFETs in both the logic circuits and memory cells. More than two threshold voltages are thus provided for the resulting device.

In FIG. 14 and step 202 of the method 200, the gate dielectric layer 112 is deposited in the recesses 110 in a first region (e.g., the first n-type region 50N-1), a second region (e.g., the second n-type region and/or the second p-type region 50N-2/50P-2), and a third region (e.g., the first p-type region 50P-1). The gate dielectric layer 112 wraps around all (e.g., four) sides of the second nanostructures 66. In the illustrated embodiment in FIG. 14, the gate dielectric layer 112 is multilayered, including an interfacial layer 112A and an overlying high-k dielectric layer 112B. In the illustrated embodiment, the high-k dielectric layer 112B is also multilayered, including a first high-k dielectric layer 112B-1 and a second high-k dielectric layer 112B-2.

In accordance with some embodiments, the interface layer 112A is an oxide of the material of the second nanostructures 66, such as silicon oxide, and may be formed by oxidizing the second nanostructures 66 in the recesses 110. The interface layer 112A may also be formed by a deposition process, such as a chemical vapor deposition (CVD) process, a physical vapor deposition (PVD) process, an atomic layer deposition (ALD) process, or the like.

In accordance with some embodiments, the first high-k dielectric layer 112B-1 has a k-value greater than about 7.0, and may include a metal oxide or a silicate of Hf, Al, Zr, La, Mg, Ba, Ti, Pb, and combinations thereof. The formation methods of the first high-k dielectric layer 112B-1 may include MBD, ALD, PECVD, and the like. In a particular embodiment, the first high-k dielectric layer 112B-1 is formed from hafnium oxide (HfOₓ). The second high-k dielectric layer 112B-2 may be formed from an oxide, nitride, or carbide of a dipole-inducing element such as La, Al, Sc, Ru, Zr, Er, Mg. Sr, and combinations thereof. The second high-k dielectric layer 112B-2 may be formed by PVD, CVD, ALD, or other suitable deposition methods. In a particular embodiment, the second high-k dielectric layer 112B-2 is formed from lanthanum oxide (LaOₓ). In furtherance of some embodiments, the thickness of the second high-k dielectric layer 112B-2 is different in each of the regions 50N-1, 50N-2/50P-2, and 50P-1. For example, the thickness of the second high-k dielectric layer 112B-2 in the region 50N-1 may be larger than the thickness in other regions, and the thickness of the second high-k dielectric layer 112B-2 in the region 50P-1 may be the smallest among all. The different thicknesses of the second high-k dielectric layer 112B-2 induce different concentrations of dipole-inducing element diffusing into the first high-k dielectric layer 112B-1, which further fine tunes the transistor threshold voltages in different regions. Although the high-k dielectric layer 112B is illustrated as utilizing multiple layers, some embodiments may utilize a single layer. For example, the high-k dielectric 112B may be a single layer essentially of hafnium oxide.

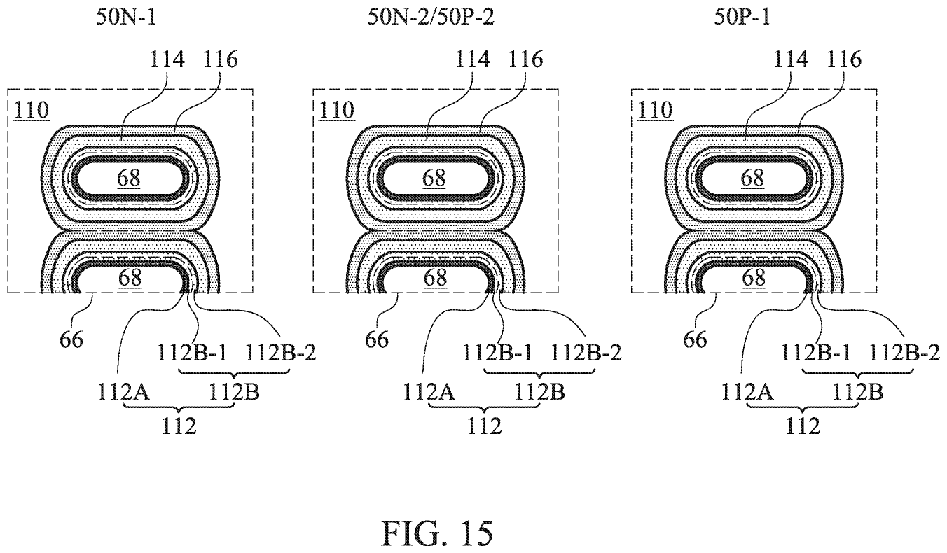

In FIG. 15 and step 204 of the method 200, a first work function (WF) layer 114 is deposited on the gate dielectric layer 112 in regions 50N-1, 50N-2/50P-2, and 50P-1. As will be subsequently described in greater detail, the first WF layer 114 will be patterned to remove portions of the first WF layer 114 in the first and second regions 50N-1 and 50N-2/50P-2 while leaving portions of the first WF layer 114 in the third region 50P-1. The first WF layer 114 may be referred to as a “first p-type WF layer”. The first WF layer 114 includes any acceptable material to tune a work function of a device to a desired amount given the application of the device to be formed, and may be deposited using any acceptable deposition process. For example, when the first WF layer 114 is a p-type WF layer, it may be formed of a p-type work function metal (PWFM) such as titanium nitride (TiN), tantalum nitride (TaN), combinations thereof, or the like, which may be deposited by ALD, CVD, PVD, or the like. Although the first WF layer 114 is shown as being single layered, the first WF layer 114 can be multilayered. For example, the first WF layer 114 can include a layer of titanium nitride (TiN) and an overlying layer of tantalum nitride (TaN).

Still referring to FIG. 15, a sacrificial layer 116 is deposited on the first WF layer 114 in regions 50N-1, 50N-2/50P-2, and 50P-1. The layer 116 is termed a sacrificial layer as it will be removed from the device in subsequent steps. The sacrificial layer 116 is formed to a thickness that is sufficient to cause merging of the portions of the sacrificial layer 116 between the second nanostructures 66 in the regions 50N-1, 50N-2/50P-2, and 50P-1. As a result, the portions of the recesses 110 between the second nanostructures 66 are completely filled by the sacrificial layer 116, so that no gaps can be remained between the second nanostructures 66. By not leaving gaps between the second nanostructures 66, manufacturing case can be improved, particularly in advanced semiconductor nodes with small feature sizes, as resist materials used in subsequent lithography processes once entering the gaps would be difficult to remove and deteriorate device performance. Therefore, material and deposition method for forming the sacrificial layer 116 is not arbitrarily picked, but to exhibit high etch selectivity and strong gap filling capability. In an embodiment, the sacrificial layer 116 includes a metal oxide such as alumina (Al₂O₃) and is deposited using a CVD method, such as plasma enhanced chemical vapor deposition (PECVD) process. In various embodiments, the sacrificial layer 116 may include silicon nitride, lanthanum oxide, silicon (such as polysilicon), silicon carbonitride, silicon oxy carbonitride, aluminum nitride, aluminum oxynitride, a combination thereof, or other suitable materials. In some embodiments, the sacrificial layer 116 may be deposited using ALD, CVD, PVD, or other suitable processes. In some embodiments, the sacrificial layer 116 is formed to a thickness in a range of about 5 Å to about 40 Å, such as in a range of about 20 Å to about 25 Å.

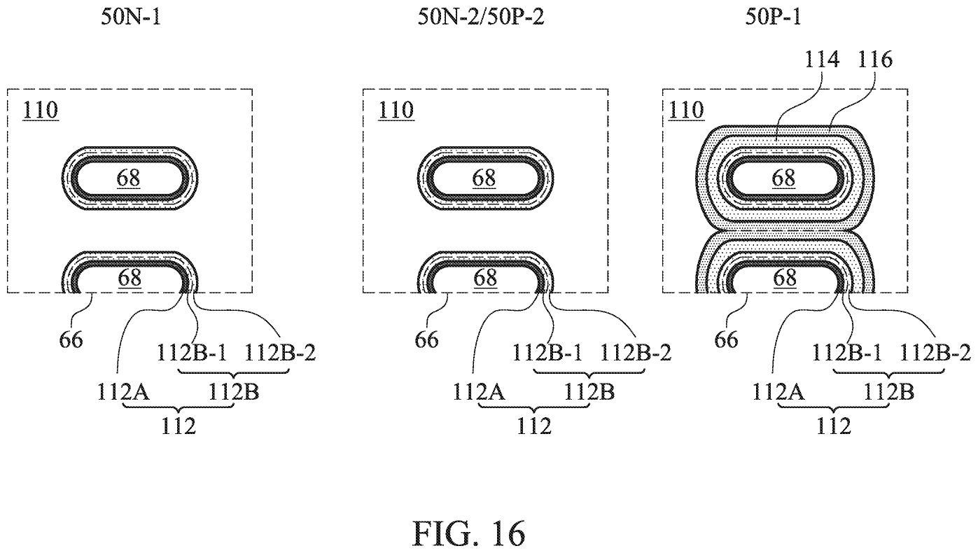

In FIG. 16 and step 206 of the method 200, portions of the sacrificial layer 116 and the first WF layer 114 are removed from the regions 50N-1 and 50N-2/50P-2. Removing the portions of the sacrificial layer 116 and the first WF layer 114 expands the recesses 110 in the regions 50N-1 and 50N-2/50P-2 to re-expose the gate dielectric layer 112 in the regions 50N-1 and 50N-2/50P-2. The removal may be performed by acceptable lithography and etching techniques. The etching may include any acceptable etch process, such as dry etching, wet etching, reactive ion etching (RIE), and/or other suitable processes.

In some embodiments, a patterned etch mask (not separately illustrated) is formed over the device, particularly over the region 50P-1. For example, the etch mask layer may include a bottom anti-reflective coating (BARC) material that provides a platform for photoresist coating and photoresist patterning. In an embodiment, the etch mask layer is formed by spin coating a BARC material over the sacrificial layer 116 and baking the BARC material (for example, at a temperature in a range about 100° C. to about 200° C.) to cause cross-linking within the BARC material. Subsequently, the etch mask layer is patterned to form openings exposing the regions 50N-1 and 50N-2/50P-2 therein, while rest of the etch mask layer still covers the device. In an embodiment, the patterning of the etch mask layer includes a lithography process that forms a resist (or photoresist) layer (not separately illustrated) over the etch mask layer by spin coating, performs a pre-exposure baking process, performs an exposure process, perform a post-exposure baking process, and develops the exposed resist layer in a developer solution. After the development, the resist layer becomes a resist pattern that corresponds with the photomask. The exposure process can be implemented using a photomask or using a maskless lithography process such as e-beam writing, ion-beam writing, or combinations thereof. Using the resist pattern as an etch mask, the etch mask layer is etched (for example, using an anisotropic etching process) to form the openings over the regions 50N-1 and 50N-2/50P-2. Then, the sacrificial layer 116 and the first WF layer 114 are etched through the openings.

In some embodiments, a single etch is performed to remove the portions of the sacrificial layer 116 and the first WF layer 114. The single etch may be selective to the materials of the sacrificial layer 116 and the first WF layer 114 (e.g., selectively etches the materials of the sacrificial layer 116 and the first WF layer 114 at a faster rate than the material(s) of the gate dielectric layer 112). For example, the sacrificial layer 116 is formed of alumina and the first WF layer 114 is formed of titanium nitride, they may both be removed by a wet etch using ammonium hydroxide (NH₄OH). In some embodiments, a first etch is performed to remove the portions of the sacrificial layer 116 and a second etch is performed to remove the portions of the first WF layer 114. The first etch may be selective to the sacrificial layer 116 (e.g., selectively etches the material of the sacrificial layer 116 at a faster rate than the material of the first WF layer 114). The second etch may be selective to the first WF layer 114 (e.g., selectively etches the material of the first WF layer 114 at a faster rate than the material of the gate dielectric layer 112). For example, the first etch may use dilute hydrofluoric (dHF) acid, and the second etch may use ammonium hydroxide (NH₄OH).

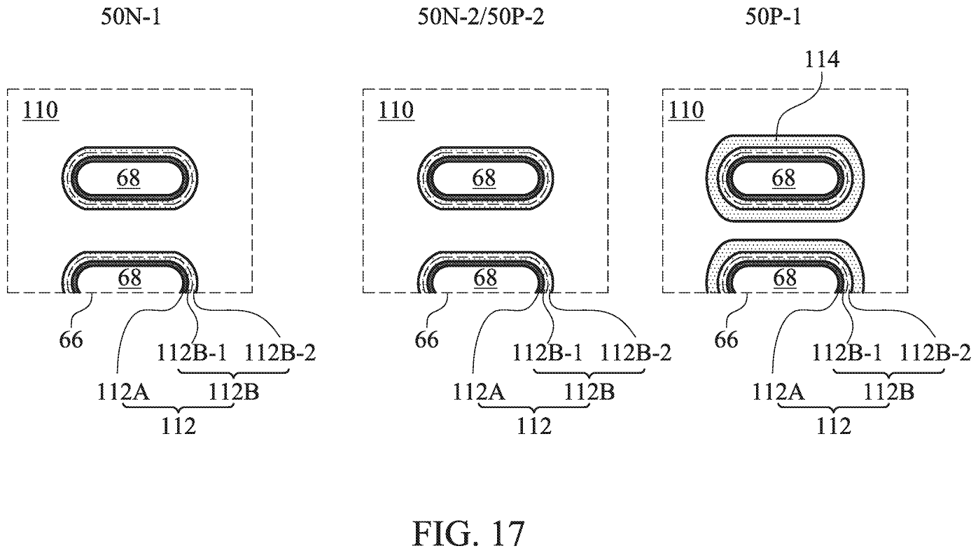

After the removal of the portions of the sacrificial layer 116 and the first WF layer 114 from the regions 50N-1 and 50N-2/50P-2, the patterned etch mask is removed from the device, for example, using stripping or ashing. After the patterned etch mask is removed, the region 50P-1 is exposed. An extra etch is then performed to remove the remaining portions of the sacrificial layer 116 from the region 50P-1. The extra etch may be selective to the sacrificial layer 116 (e.g., selectively etches the material of the sacrificial layer 116 at a faster rate than the material of the first WF layer 114). In some embodiments, the extra etch may use dilute hydrofluoric (dHF) acid. After the removal of the sacrificial layer 116 from the region 50P-1 (as also from the device), the first WF layer 114 is exposed in the region 50P-1. The resultant structure is illustrated in FIG. 17.

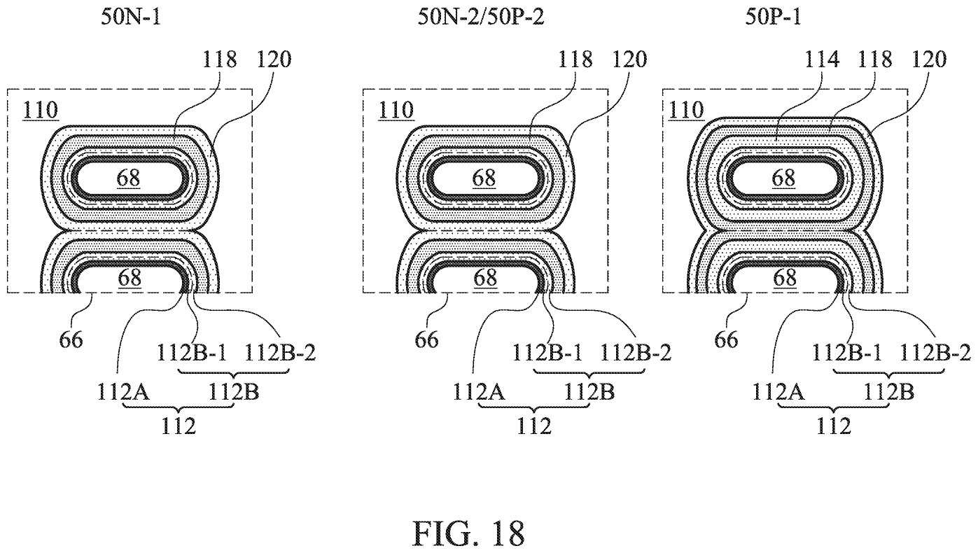

In FIG. 18 and step 208 of the method 200, a second WF layer 118 is deposited on the gate dielectric layer 112 in regions 50N-1 and 50N-2/50P-2, and on the first WF layer 114 in the region 50P-1. As will be subsequently described in greater detail, the second WF layer 118 will be patterned to remove portions of the second WF layer 118 in the region 50N-1 while leaving portions of the second WF layer 118 in the regions 50N-2/50P-2 and 50P-1. The second WF layer 118 has the same conductivity type with the first WF layer 114. The second WF layer 118 may be referred to as a “second p-type WF layer”. The second WF layer 118 includes any acceptable material to tune a work function of a device to a desired amount given the application of the device to be formed, and may be deposited using any acceptable deposition process. For example, when the second WF layer 118 is a p-type WF layer, it may be formed of a p-type work function metal (PWFM) such as titanium nitride (TiN), tantalum nitride (TaN), combinations thereof, or the like, which may be deposited by ALD, CVD, PVD, or the like. Although the second WF layer 118 is shown as being single layered, the second WF layer 118 can be multilayered. For example, the second WF layer 118 can include a layer of titanium nitride (TiN) and an overlying layer of tantalum nitride (TaN).

In some embodiments, the first WF layer 114 and the second WF layer 118 may include different materials, and a boundary between the first WF layer 114 and the second WF layer 118 is discernable. For example, the first WF layer 114 may include a layer of titanium nitride (TiN), and the second WF layer 118 may include a layer of tantalum nitride (TaN). In some alternative embodiments, the first WF layer 114 and the second WF layer 118 may include the same material but different grain sizes, and a boundary between the first WF layer 114 and the second WF layer 118 is still discernable. For example, the first WF layer 114 may include a layer of titanium nitride (TiN) with relatively smaller grain size, and the second WF layer 118 may include a layer of titanium nitride (TiN) with relatively larger grain size. The different grain sizes (e.g., an average grain size difference of 30% to 80%) may be due to different deposition techniques applied during the formation of respective WF layers. For example, the first WF layer 114 with a relatively smaller grain size may be deposited in an ALD process, and the second WF layer 118 with a relatively larger grain size may be deposited in a PVD process. In some other alternative embodiments, the first WF layer 114 and the second WF layer 118 may include the same material, such as titanium nitride (TiN), and the similar grain size, and a boundary between the first WF layer 114 and the second WF layer 118 may not be discernable.

The second WF layer 118 is formed to a thickness that is sufficient to cause merging of the portions of the second WF layer 118 between the second nanostructures 66 in the region 50P-1. As a result, the portions of the recesses 110 between the second nanostructures 66 are completely filled by the second WF layer 118, so that no gaps can be remained between the second nanostructures 66 in the region 50P-1. Since the recesses 110 in the regions 50N-1 and 50N-2/50P-2 are relatively larger due to the removal of the first WF layer 114 from the regions 50N-1 and 50N-2/50P-2, the second WF layer 118 wraps around the gate dielectric layer 112 and the second nanostructures 66 but does not completely fill the gaps between the second nanostructures 66 in the regions 50N-1 and 50N-2/50P-2.

Still referring to FIG. 18, a barrier layer 120 is deposited on the second WF layer 118 in regions 50N-1, 50N-2/50P-2, and 50P-1. The barrier layer 120 is formed to a thickness that is sufficient to cause merging of the portions of the barrier layer 120 between the second nanostructures 66 in the regions 50N-1 and 50N-2/50P-2. As a result, the portions of the recesses 110 between the second nanostructures 66 are completely filled by the barrier layer 120, so that no gaps can be remained between the second nanostructures 66. Since the gaps between the second nanostructures 66 are already completely filled with the second WF layer 118 in the region 50P-1, the barrier layer 120 is not vertically stacked between two adjacent second nanostructures 66 in the region 50P-1. By not leaving gaps between the second nanostructures 66, manufacturing case can be improved, particularly in advanced semiconductor nodes with small feature sizes, as resist materials used in subsequent lithography processes once entering the gaps would be difficult to remove and deteriorate device performance. Therefore, material and deposition method for forming the barrier layer 120 is not arbitrarily picked, but to exhibit high etch selectivity and strong gap filling capability. In an embodiment, the barrier layer 120 includes a carbonitride, such as a tungsten carbonitride (WCN), and is deposited using a CVD method, such as plasma enhanced chemical vapor deposition (PECVD) process. In various embodiments, the barrier layer 120 may include lanthanum oxide, aluminum oxide (alumina), titanium oxide, tantalum nitride, silicon, silicon germanium, silicon oxide, silicon carbonitride, tungsten, fluorine-free tungsten (FFW), a combination thereof, or other suitable materials. In some embodiments, the barrier layer 120 may be deposited using ALD, CVD, PVD, or other suitable processes. In some embodiments, the barrier layer 120 is formed to a thickness in a range of about 5 Å to about 40 Å, such as in a range of about 20 Å to about 25 Å.

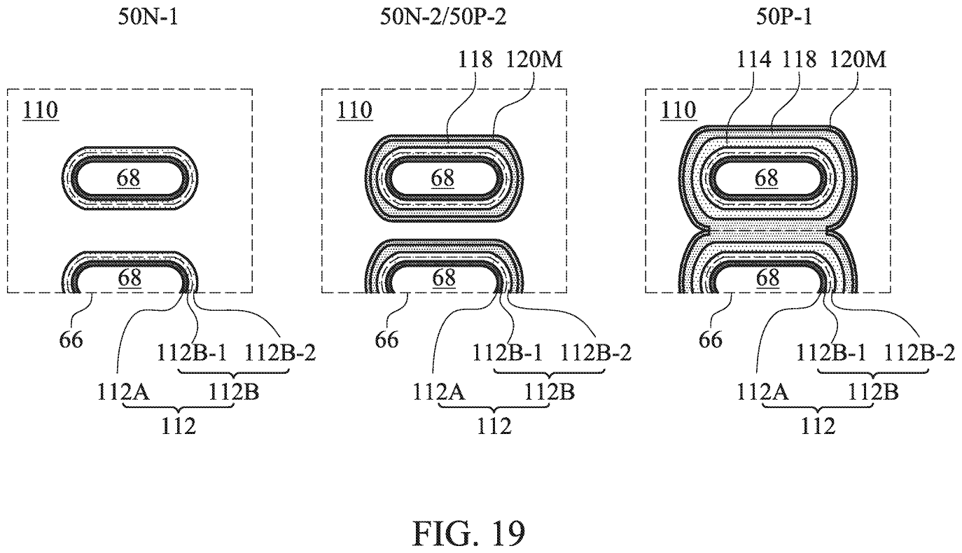

In FIG. 19 and step 210 of the method 200, portions of the barrier layer 120 and the second WF layer 118 are removed from the region 50N-1. Removing the portions of the barrier layer 120 and the second WF layer 118 expands the recesses 110 in the region 50N-1 to re-expose the gate dielectric layer 112 in the region 50N-1. The removal may be performed by acceptable lithography and etching techniques. The etching may include any acceptable etch process, such as dry etching, wet etching, reactive ion etching (RIE), and/or other suitable processes.

In some embodiments, a patterned etch mask (not separately illustrated) is formed over the device, particularly over the regions 50N-2/50P-2 and 50P-1. For example, the etch mask layer may include a bottom anti-reflective coating (BARC) material that provides a platform for photoresist coating and photoresist patterning. In an embodiment, the etch mask layer is formed by spin coating a BARC material over the barrier layer 120 and baking the BARC material (for example, at a temperature in a range about 100° C. to about 200° C.) to cause cross-linking within the BARC material. Subsequently, the etch mask layer is patterned to form openings exposing the region 50N-1 therein, while rest of the etch mask layer still covers the device. In an embodiment, the patterning of the etch mask layer includes a lithography process that forms a resist (or photoresist) layer (not separately illustrated) over the etch mask layer by spin coating, performs a pre-exposure baking process, performs an exposure process, perform a post-exposure baking process, and develops the exposed resist layer in a developer solution. After the development, the resist layer becomes a resist pattern that corresponds with the photomask. The exposure process can be implemented using a photomask or using a maskless lithography process such as e-beam writing, ion-beam writing, or combinations thereof. Using the resist pattern as an etch mask, the etch mask layer is etched (for example, using an anisotropic etching process) to form the openings over the region 50N-1. Then, the barrier layer 120 and the second WF layer 118 are etched through the openings.

In some embodiments, a single etch is performed to remove the portions of the barrier layer 120 and the second WF layer 118. The single etch may be selective to the materials of the barrier layer 120 and the second WF layer 118 (e.g., selectively etches the materials of the barrier layer 120 and the second WF layer 118 at a faster rate than the material(s) of the gate dielectric layer 112). For example, the barrier layer 120 is formed of tungsten carbonitride and the second WF layer 118 is formed of titanium nitride, they may both be removed by a wet etch using ammonium hydroxide (NH₄OH). In some embodiments, a first etch is performed to remove the portions of the barrier layer 120 and a second etch is performed to remove the portions of the second WF layer 118. The first etch may be selective to the barrier layer 120 (e.g., selectively etches the material of the barrier layer 120 at a faster rate than the material of the second WF layer 118). The second etch may be selective to the second WF layer 118 (e.g., selectively etches the material of the second WF layer 118 at a faster rate than the material of the gate dielectric layer 112). For example, the first etch may use dilute hydrofluoric (dHF) acid, and the second etch may use ammonium hydroxide (NH₄OH).

After the removal of the portions of the barrier layer 120 and the second WF layer 118 from the region 50N-1, the patterned etch mask is removed from the device, for example, using stripping or ashing. After the patterned etch mask is removed, the regions 50N-2/50P-2 and 50P-1 are exposed. An extra etch is then performed to remove the remaining portions of the barrier layer 120. The extra etch may be selective to the barrier layer 120 (e.g., selectively etches the material of the barrier layer 120 at a faster rate than the material of the second WF layer 118). In some embodiments, the extra etch may use dilute hydrofluoric (dHF) acid. As shown in FIG. 19, at the interface between the barrier layer 120 and the second WF layer 118, an intermixing layer of the materials from the barrier layer 120 and the second WF layer 118 may remain as a residual thin film in the regions 50N-2/50P-2 and 50P-1, denoted as the intermixing layer 120M. The intermixing layer 120M is formed due to the diffusion of the metal element in the barrier layer 120 into a thin surface layer of the second WF layer 118. In the embodiment that the barrier layer 120 includes tungsten carbonitride and the second WF layer 118 includes titanium nitride, the intermixing layer 120M contains tungsten and titanium. In some embodiments, the intermixing layer 120M is formed to a thickness in a range of about 1 Å to about 5 Å.

In some embodiments, an anneal process may be performed to promote the formation of the intermixing layer 120M as the diffusion of tungsten into the second WF layer 118 may be effective in further fine tuning the threshold voltages. The anneal process is performed before the removal of the barrier layer 120 from the regions 50N-2/50P-2 and 50P-1, yet either before or after the removal of the barrier layer 120 from the region 50N-1. In one example, a low-temperature anneal may be performed in an ambient containing an inert gas. The inert gas may be argon (Ar), helium (He), xenon (Xe), neon (Ne), krypton (Kr), Radon (Rn), combinations thereof, or the like. The low-temperature anneal may be performed at a temperature of from about 150° C. to about 500° C.

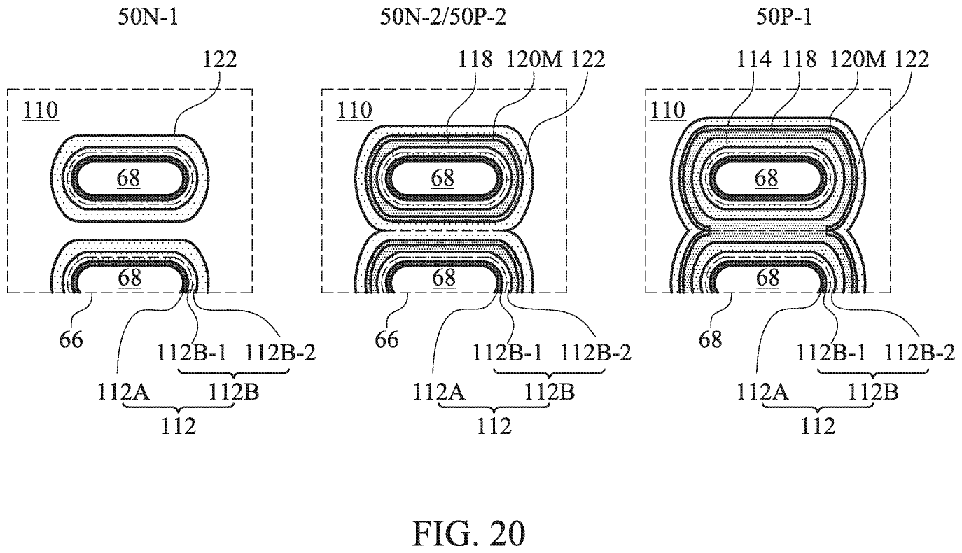

In FIG. 20 and step 212 of the method 200, a third work function (WF) layer 122 is deposited on the gate dielectric layer 112 in the region 50N-1 and on the intermixing layer 120M in the regions 50N-2/50P-2 and 50P-1. The third WF layer 122 may be referred to as an “n-type WF layer”. The third WF layer 122 includes any acceptable material to tune a work function of a device to a desired amount given the application of the device to be formed, and may be deposited using any acceptable deposition process. For example, when the third WF layer 122 is an n-type WF layer, it may be formed of an n-type work function metal (NWFM) such as titanium aluminum (TiAl), titanium aluminum carbide (TiAIC), titanium aluminum nitride (TiAIN), combinations thereof, or the like, which may be deposited by ALD, CVD, PVD, or the like. Although the third WF layer 122 is shown as being single layered, the third WF layer 122 can be multilayered. For example, the third WF layer 122 can include a layer of titanium aluminum (TiAl) and an overlying layer of titanium aluminum nitride (TiAIN).

The third WF layer 122 is formed to a thickness that is sufficient to cause merging of the portions of the third WF layer 122 between the second nanostructures 66 in the region 50N-2/50P-2. As a result, the portions of the recesses 110 between the second nanostructures 66 are completely filled by the third WF layer 122, so that no gaps can be remained between the second nanostructures 66 in the region 50N-2/50P-2. Since the gaps between the second nanostructures 66 are already completely filled with the second WF layer 118 in the region 50P-1, the third WF layer 122 is not vertically stacked between two adjacent second nanostructures 66 in the region 50P-1. Since the recesses 110 in the region 50N-1 are relatively larger due to the removal of the second WF layer 118 from the region 50N-1, the third WF layer 122 wraps around the gate dielectric layer 112 and the second nanostructures 66 but does not completely fill the gaps between the second nanostructures 66 in the region 50N-1.

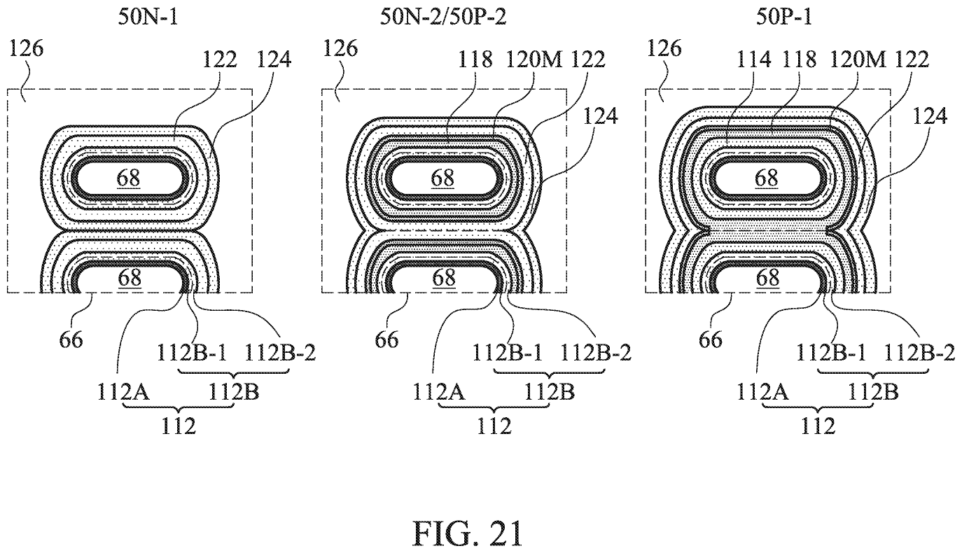

In FIG. 21 and step 214 of the method 200, a capping layer 124 is deposited on the third WF layer 122, and a fill layer 126 is formed on the capping layer 124. The capping layer 124 includes any acceptable material to promote adhesion and prevent diffusion. For example, the capping layer 124 may be formed of a metal or metal nitride such as titanium nitride, titanium aluminide, titanium aluminum nitride, silicon-doped titanium nitride, tantalum nitride, or the like, which may be deposited by ALD, CVD, PVD, or the like. The fill layer 126 includes any acceptable material of a low resistance. For example, the fill layer 126 may be formed of a metal such as tungsten, aluminum, cobalt, ruthenium, combinations thereof or the like, which may be deposited by ALD, CVD, PVD, or the like. The fill layer 126 fills the remaining portions of the recesses 110. In one example, the capping layer 124 is formed of titanium nitride, and the fill layer 126 is formed of tungsten.

As the recesses 110 in the region 50P-1 have the smallest volume left for depositing the capping layer 124 and the fill layer 126 in a comparison with other recesses 110 in the regions 50N-1 and 50N-2/50P-2, the fill layer 126 has the smallest volume in the region 50P-1. Meanwhile, the fill layer 126 has the largest volume in the region 50N-1. In furtherance of some embodiments, the recesses 110 in the region 50P-1 may be already filled up with the layers formed prior to the depositing of the fill layer 126, such that the fill layer 126 is not deposited on sidewalls of the previously formed layers in the recesses 110 but deposited above the top surface of the topmost nanostructure 66 (e.g., in a region denoted as 50L in FIG. 13B). Still further, the fill layer 126 in the region 50P-1 may even be removed in a later gate pull-back process. FIG. 22 illustrates such an embodiment, showing regions similar to the region 50L in FIG. 13B. As shown in FIG. 22, the fill layer 126 has the largest volume in the region 50N-1 and a smaller volume in the region 50N-2/50P-2, but is substantially free from the region 50P-1. In some embodiments, the fill layer 126 is even free from the region 50N-2/50P-2. By reducing the amount of bulk tungsten in proximity to the underneath WF layers in the regions 50N-2/50P-2 and 50P-1, a better threshold hold tuning can be achieved. Meanwhile, bulk tungsten is still in proximity to the underneath WF layers in the region 50N-1, which helps improving MBE and time dependent dielectric breakdown (TDDB) window for logic circuits formed in the region 50N-1.

At the conclusion of step 214, the gate electrode layer 128 in the region 50N-1 includes the third WF layer 122; the gate electrode layer 128 in the region 50N-2/50P-2 includes the second WF layer 118, the third WF layer 122, and the intermixing layer 120M therebetween; and the gate electrode layer 128 in the region 50P-1 includes the first WF layer 114, the second WF layer 118, the third WF layer 122, and the intermixing layer 120M between the second WF layer 118 and the third WF layer 122. The first WF layer 114, the second WF layer 118, and the third WF layer 122 are designed to provide different work functions. For example, the first WF layer 114 and the second WF layer 118 provide p-type work functions, and the third WF layer 122 provides an n-type work function. However, since the second WF layer 118 and/or the first WF layer 114 separate the third WF layer 122 from the gate dielectric layer 112 in the regions 50N-2/50P-2 and 50P-1, they fine tune the work function of the third WF layer 122. One reason is that metal elements (e.g., Al) in the third WF layer 122 may less diffuse into the underneath gate dielectric layer 112 due to the larger distance.

The device may undergo further processing to form various features and regions known in the art. For example, subsequent processing may form contact openings, contact metal, as well as various contacts/vias/lines and multilayers interconnect features (e.g., metal layers and interlayer dielectrics), configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200.

Although not intended to be limiting, one or more embodiments of the present disclosure provide many benefits to a semiconductor device and the formation thereof. For example, embodiments of the present disclosure provide different configurations of gate material layers available to form transistors with different threshold voltages. Using embodiments of the present disclosure, work function layers in metal gate structures can be formed with a less stringent process control to achieve different threshold voltages more easily. Furthermore, the present embodiments can be readily integrated into existing CMOS fabrication processes.

In one exemplary aspect, the present disclosure is directed to a method of manufacturing a semiconductor device. The method includes forming a first stack of nanostructures spaced vertically one from another in a first region of the semiconductor device, a second stack of nanostructures spaced vertically one from another in a second region of the semiconductor device, and a third stack of nanostructures spaced vertically one from another in a third region of the semiconductor device, depositing a first work function layer wrapping around each of the nanostructures in the first, second, and third regions, removing the first work function layer from the first and second regions, depositing a second work function layer wrapping around each of the nanostructures in the first and second regions and over the first work function layer in the third region, removing the second work function layer from the first region, depositing a third work function layer wrapping around each of the nanostructures in the first region and over the second work function layer in the second and third regions, and forming a capping layer over the third work function layer in the first, second, and third regions. In some embodiments, the first work function layer and the second work function layer are of a first conductivity type, and the third work function layer is of a second conductivity type that is opposite to the first conductivity type. In some embodiments, the first conductivity type is p-type and the second conductivity type is n-type. In some embodiments, the first work function layer and the second work function layer include different work function materials. In some embodiments, the first work function layer and the second work function layer include a same work function material but with different grain sizes. In some embodiments, the first work function layer and the second work function layer include a same work function material with a same grain size. In some embodiments, the method further includes after the depositing of the second work function layer, forming a barrier layer over the second work function layer in the first, second, and third regions, and after the removing of the second work function layer from the first region, removing the barrier layer from the second and third regions, the removing of the second work function layer from the first region including removing the barrier layer from the first region. In some embodiments, the removing of the barrier layer from the second and third regions results in an intermixing layer over the second work function layer in the second and third regions. In some embodiments, the intermixing layer includes a first metal element from the second work function layer and a second metal element from the barrier layer. In some embodiments, the third work function layer is in physical contact with the intermixing layer in the second and third regions.

In another exemplary aspect, the present disclosure is directed to a method. The method includes providing a structure having a first region and a second region, a first stack of nanostructures spaced vertically one from another in the first region, and a second stack of nanostructures spaced vertically one from another in the second region, forming a dielectric layer wrapping around each of the nanostructures in the first and second regions, forming a p-type work function layer over the dielectric layer in the first and second regions, depositing a barrier layer over the p-type work function layer in the first and second regions, removing the barrier layer and the p-type work function layer from the first region, thereby exposing the dielectric layer in the first region, removing the barrier layer from the second region, resulting in a thin film over the p-type work function layer in the second region, and forming an n-type work function layer over the dielectric layer in the first region and over the thin film in the second region. In some embodiments, the thin film includes a first metal element from the p-type work function layer and a second metal element from the barrier layer. In some embodiments, the first metal element is titanium, and the second metal element is tungsten. In some embodiments, the method further includes after the forming of the dielectric layer, forming a sacrificial work function layer over the dielectric layer in the first and second regions, forming a metal-containing layer over the sacrificial work function layer in the first and second regions, and removing the sacrificial work function layer and the metal-containing layer from the first and second regions, thereby exposing the dielectric layer in the first and second regions. In some embodiments, the p-type work function layer and the sacrificial work function layer have a same conductivity type. In some embodiments, after the depositing of the barrier layer, the barrier layer fills up gaps between adjacent ones of the nanostructures in the first and second regions. In some embodiments, after the forming of the n-type work function layer, the n-type work function layer fills up gaps between adjacent ones of the nanostructures in the second region, and gaps between adjacent ones of the nanostructures in the first region remain.

In yet another exemplary aspect, the present disclosure is directed to a semiconductor device. The semiconductor device includes a substrate, a first stack of nanostructures suspended above a first region of the substrate, a second stack of nanostructures suspended above a second region of the substrate, a first work function layer wrapping around each of the nanostructures in the first region, a second work function layer over the first work function layer in the first region, a third work function layer wrapping around each of the nanostructures in the second region and over the second work function layer in the first region, and a metal-containing thin film stacked between the second work function layer and the third work function layer in the first region. In some embodiments, the first work function layer and the second work function layer are p-type, and the third work function layer is n-type. In some embodiments, the semiconductor device of further includes a third stack of nanostructures suspended above a third region of the substrate. The second work function layer wraps around each of the nanostructures in the third region, the third work function layer is over the second work function layer in the third region, and the metal-containing thin film is stacked between the second work function layer and the third work function layer in the third region.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a first stack of nanostructures spaced vertically one from another in a first region of the semiconductor device, a second stack of nanostructures spaced vertically one from another in a second region of the semiconductor device, and a third stack of nanostructures spaced vertically one from another in a third region of the semiconductor device;
depositing a first work function layer wrapping around each of the nanostructures in the first, second, and third regions;
removing the first work function layer from the first and second regions;
depositing a second work function layer wrapping around each of the nanostructures in the first and second regions and over the first work function layer in the third region;
removing the second work function layer from the first region;
depositing a third work function layer wrapping around each of the nanostructures in the first region and over the second work function layer in the second and third regions; and
forming a capping layer over the third work function layer in the first, second, and third regions.

2. The method of claim 1, wherein the first work function layer and the second work function layer are of a first conductivity type, and the third work function layer is of a second conductivity type that is opposite to the first conductivity type.

3. The method of claim 2, wherein the first conductivity type is p-type and the second conductivity type is n-type.

4. The method of claim 1, wherein the first work function layer and the second work function layer include different work function materials.

5. The method of claim 1, wherein the first work function layer and the second work function layer include a same work function material but with different grain sizes.

6. The method of claim 1, wherein the first work function layer and the second work function layer include a same work function material with a same grain size.

7. The method of claim 1, further comprising:
after the depositing of the second work function layer, forming a barrier layer over the second work function layer in the first, second, and third regions; and
after the removing of the second work function layer from the first region, removing the barrier layer from the second and third regions, wherein the removing of the second work function layer from the first region includes removing the barrier layer from the first region.

8. The method of claim 7, wherein the removing of the barrier layer from the second and third regions results in an intermixing layer over the second work function layer in the second and third regions.

9. The method of claim 8, wherein the intermixing layer includes a first metal element from the second work function layer and a second metal element from the barrier layer.

10. The method of claim 8, wherein the third work function layer is in physical contact with the intermixing layer in the second and third regions.

11. A method, comprising:
providing a structure having a first region and a second region, a first stack of nanostructures spaced vertically one from another in the first region, and a second stack of nanostructures spaced vertically one from another in the second region;
forming a dielectric layer wrapping around each of the nanostructures in the first and second regions;
forming a p-type work function layer over the dielectric layer in the first and second regions;
depositing a barrier layer over the p-type work function layer in the first and second regions;
removing the barrier layer and the p-type work function layer from the first region, thereby exposing the dielectric layer in the first region;
removing the barrier layer from the second region, resulting in a thin film over the p-type work function layer in the second region; and
forming an n-type work function layer over the dielectric layer in the first region and over the thin film in the second region.

12. The method of claim 11, wherein the thin film includes a first metal element from the p-type work function layer and a second metal element from the barrier layer.

13. The method of claim 12, wherein the first metal element is titanium, and the second metal element is tungsten.

14. The method of claim 11, further comprising:
after the forming of the dielectric layer, forming a sacrificial work function layer over the dielectric layer in the first and second regions;
forming a metal-containing layer over the sacrificial work function layer in the first and second regions; and
removing the sacrificial work function layer and the metal-containing layer from the first and second regions, thereby exposing the dielectric layer in the first and second regions.

15. The method of claim 14, wherein the p-type work function layer and the sacrificial work function layer have a same conductivity type.

16. The method of claim 11, wherein after the depositing of the barrier layer, the barrier layer fills up gaps between adjacent ones of the nanostructures in the first and second regions.

17. The method of claim 11, wherein after the forming of the n-type work function layer, the n-type work function layer fills up gaps between adjacent ones of the nanostructures in the second region, and gaps between adjacent ones of the nanostructures in the first region remain.

18. A semiconductor device, comprising:
a substrate;
a first stack of nanostructures suspended above a first region of the substrate;
a second stack of nanostructures suspended above a second region of the substrate;
a first work function layer wrapping around each of the nanostructures in the first region;
a second work function layer over the first work function layer in the first region;
a third work function layer wrapping around each of the nanostructures in the second region and over the second work function layer in the first region; and
a metal-containing thin film stacked between the second work function layer and the third work function layer in the first region.

19. The semiconductor device of claim 18, wherein the first work function layer and the second work function layer are p-type, and the third work function layer is n-type.

20. The semiconductor device of claim 18, further comprising:
a third stack of nanostructures suspended above a third region of the substrate,
wherein the second work function layer wraps around each of the nanostructures in the third region, the third work function layer is over the second work function layer in the third region, and the metal-containing thin film is stacked between the second work function layer and the third work function layer in the third region.
